(19) United States
(12) Patent Application Publication
(10) Pub. No.: US 2005/0284654 A1
(43) Pub. Date: Dec. 29, 2005

(54) Structure of terminal member

(75) Inventor: Bunya Sato, Fukushima (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION

(21) Appl. No.: 11/214,351

(22) Filed: Aug. 29, 2005

Related U.S. Application Data
(62) Division of application No. 10/835,776, filed on Apr. 30, 2004.

(30) Foreign Application Priority Data
May 19, 2003 (JP) 2003-141115

(51) Int. Cl. H05K 7/20

(52) U.S. Cl. 174/252

(57) ABSTRACT

A composite board is fixed by solder to an electrode land formed on a circuit board having an electric wiring. The composite board and another metal plate are bonded by using an electric welding method or the like. By bonding a metal plate of a low resistance or a non-metal plate to the composite board, heat of high temperature or a large current which is generated upon electric wiring can be made difficult to be transferred to a lower portion of the composite board. A structure of a terminal member in which it is possible to prevent the solder under the composite board from being diffused, the solder is not scattered to the periphery, and a short-circuit is not caused is obtained. The terminal member to form the circuit board which is more mechanically and electrically stable is provided.

### BACKGROUND OF THE INVENTION

1. Field of the Invention

The invention relates to a structure of a terminal member which is connected mainly to a printed circuit board.

2. Description of the Related Arts

In recent years, miniaturization of electronic devices has been progressed as in notebook-sized personal computers and cellular phones. Such miniaturization is realized mainly because electronic parts constructing the electronic devices can be miniaturized.

Hitherto, an electric resistance connecting method has been used as a technique for assembling electronic parts such as capacitor, semiconductor, and the like. It is a method whereby a current is supplied to a joint portion of a material to be welded and the material is welded by pressure by using its resistance heat generation. Such a kind of invention has been disclosed in JP-A-2000-114680 and JP-A-11-54895.

However, the above method has the following problem. That is, when a metal plate (hereinbelow, referred to as a metal plate A) mounted on a circuit board by soldering and another metal plate (hereinbelow, referred to as a metal plate B) are electric resistance connected, there is a possibility that solder under the metal plate A runs out due to the melting of the solder and flux vaporization upon heating by the welding. When the solder under the metal plate A runs out, strength of the soldering of the metal plate A decreases or particles of the solder scatter, so that there is a possibility that solder balls are formed and terminals of peripheral electronic parts are short-circuited.

To prevent such running-out of the solder, the metal plate A is thickened or no solder is arranged under a rectangular central portion of the metal plate A. Generally, by thickening the metal plate A to 0.3 to 0.5 mm, it is possible to prevent the solder from being melted to a certain extent and scattered at the time of the electric resistance welding with the metal plate B. However, when the metal plate is thickened, first, a whole height of the circuit board, metal plate A, and metal plate B becomes high and external dimensions of an apparatus having the circuit board therein increase. Secondly, the welding current at the time of the electric resistance welding fluctuates and when the welding current is large, there is a possibility that the solder runs out. Further, thirdly, when the metal plate A is thick, since a heat capacity of the metal plate A increases, the metal plate A absorbs heat and a temperature does not rise enough, so that an alloy layer of the solder is not formed. Thus, the defective soldering occurs and the metal plate A is easily peeled off from the circuit board and it is difficult to manage steps of a soldering reflow apparatus. Therefore, it is unpreferable to thicken the metal plate A to 0.3 to 0.5 mm.

Although an effect of preventing the running-out of the solder is not disclosed in the invention disclosed in JP-A-2000-114680, if the metal plates are electric resistance connected in an upper portion of a space portion of a copper foil land, since the solder is not easily heated to high temperature, the running-out of the solder can be prevented to a certain extent.

When the copper foil land is small, however, since a distance between a front edge of a welding rod and the solder portion is short, there is a possibility that the solder is melted by the heat upon electric resistance welding and runs out. A slight deviation of an electrode rod from the space portion of the copper foil land upon resistance welding causes the resistance welding on the solder and it also causes the possibility of the solder to be melted and run out. Further, since a soldering area of the copper foil land and the metal plate is small, there are such problems that bonding strength of the copper foil land and the metal plate is weakened, a resistance value increases, and the like.

### OBJECTS AND SUMMARY OF THE INVENTION

It is, therefore, an object of the invention to provide a terminal member in a construction in which a metal plate A mounted on a circuit board by soldering and another metal plate B are electric resistance welded, wherein by fitting a heat insulating plate of low heat conductivity to an inner layer at a center of the metal plate A, or the like, heat in an upper portion of the metal plate A is not easily propagated to a lower portion and solder under the metal plate is not melted and does not scatter to the periphery, so that a decrease in mounting strength can be prevented.

To solve the foregoing problems, according to the invention of claim 1, there is provided a structure of a terminal member comprising:
an electrode land formed on a circuit board having an electric wiring; and
a composite board fixed to the electrode land by solder,
wherein at least a part of the composite board has a triple-layer structure and a low heat conductivity plate whose heat conductivity is lower than that of at least either an upper layer or a lower layer is located in an intermediate layer.

According to the invention of claim 2, there is provided a structure of a terminal member comprising:
an electrode land formed on a circuit board having an electric wiring; and
a composite board fixed to the electrode land by solder,
wherein at least a part of the composite board has a triple-layer structure and a low heat conductivity plate whose heat conductivity is lower than that of an upper layer or a lower layer is located in an intermediate layer, and
a high heat conductivity plate whose heat conductivity is higher than that of the upper layer is located in the lower layer.

According to the invention of claim 3, there is provided a structure of a terminal member comprising:
an electrode land formed on a circuit board having an electric wiring; and
a composite board fixed to the electrode land by solder,
wherein at least a part of the composite board has a triple-layer structure and a low heat conductivity plate whose heat conductivity is lower than that of an upper layer or a lower layer is located in an intermediate layer, and
a high heat conductivity plate whose heat conductivity is higher than that of the lower layer is located in the upper layer.

According to the invention of claim 4, there is provided a structure of a terminal member comprising:
an electrode land formed on a circuit board having an electric wiring; and
a composite board fixed to the electrode land by solder,
wherein at least a part of the composite board has a double-layer structure and in one layer, a low heat conductivity plate whose heat conductivity is lower than that of the other layer is located.

According to the invention of claim 5, there is provided a structure of a terminal member comprising:
an electrode land formed on a circuit board having an electric wiring; and
a composite board fixed to the electrode land by solder,
wherein at least a part of the composite board has a triple-layer structure and a low heat conductivity plate whose heat conductivity is lower than that of a lower layer is located in an upper layer, and a metal plate of a low resistance is located in an intermediate layer.

According to the invention of claim 6, there is provided a structure of a terminal member comprising:
an electrode land formed on a circuit board having an electric wiring; and
a composite board fixed to the electrode land by solder,
wherein at least a part of the composite board has a triple-layer structure and a low heat conductivity plate whose heat conductivity is lower than that of an upper layer is located in a lower layer, and
a metal plate of a low resistance is located in an intermediate layer.

According to the structure of the terminal member constructed as mentioned above, it is possible to make it difficult to propagate high temperature in the upper portion of the composite board to the lower portion. A large current which is generated upon welding is not easily propagated to the lower portion of the composite board, so that heat generation by the large current can be prevented.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a constructional diagram of electric resistance welding according to an indirect system;

FIG. 2 is a constructional diagram of electric resistance welding according to a direct system;

FIG. 3 is a constructional diagram of ultrasonic welding;

FIG. 4 is a constructional diagram showing a flow of a current at the time of welding metal plates in a flat plate shape;

FIGS. 5A to 5C are constructional diagrams of a circuit board on which metal plates are mounted by soldering;

FIGS. 6A to 6C are a plan view, a cross sectional view, and a perspective view of a metal plate 14a, respectively;

FIG. 7 is a diagram of a circuit board 10 on which the metal plate 14a and a metal plate 14b are mounted;

FIG. 8 is a constructional diagram in which metal plates 15a and 15b of electrodes are connected to the circuit board 10 on which the metal plate is mounted;

FIG. 9 is a cross sectional view when the metal plate 14a is mounted on the circuit board 10;

FIG. 10 is a perspective view when the metal plates 14a and 14b are mounted on the circuit board 10;

FIGS. 11A and 11B are perspective views when the metal plate 14a and another metal plate 24 are electric resistance welded;

FIGS. 12A to 12C are a plan view, across sectional view, and a perspective view of a metal plate 19, respectively;

FIGS. 13A to 13C are a plan view, a cross sectional view, and a perspective view of a metal plate 20, respectively;

FIGS. 14A to 14C are a plan view, a cross sectional view, and a perspective view of a composite board 21, respectively;

FIGS. 15A to 15C are a plan view, across sectional view, and a perspective view of a composite board 25, respectively;

FIGS. 16A to 16C are a plan view, across sectional view, and a perspective view of a composite board 26, respectively;

FIGS. 17A to 17C are a plan view, across sectional view, and a perspective view of a composite board 27, respectively;

FIGS. 18A to 18C are a plan view, a cross sectional view, and a perspective view of a composite board 28, respectively;

FIGS. 19A to 19C are a plan view, a cross sectional view, and a perspective view of a composite board 29, respectively;

FIGS. 20A to 20C are a plan view, across sectional view, and a perspective view of a composite board 30, respectively;

FIGS. 21A to 21C are a plan view, a cross sectional view, and a perspective view of a composite board 38, respectively;

FIGS. 22A to 22C are a plan view, a cross sectional view, and a perspective view of a composite board 41, respectively;

FIGS. 23A to 23C are a plan view, a cross sectional view, and a perspective view of a composite board 52, respectively;

FIGS. 24A to 24C are a plan view, a cross sectional view, and a perspective view of a composite board 56, respectively;

FIGS. 25A to 25C are a plan view, a cross sectional view, and a perspective view of a composite board 76, respectively;

FIGS. 26A to 26C are a plan view, across sectional view, and a perspective view of a metal plate 64, respectively;

FIGS. 27A to 27C are a plan view, a cross sectional view, and a perspective view of a composite board 77, respectively;

FIGS. 28A to 28C are a plan view, a cross sectional view, and a perspective view of a composite board 78, respectively;

FIGS. 29A to 29C are a plan view, a cross sectional view, and a perspective view of a composite board 79, respectively;

FIGS. 30A and 30B are perspective views when the composite board 79 and a metal plate 80 are electric resistance welded;

FIGS. 31A to 31C are a plan view, across sectional view, and a perspective view of a composite board 85, respectively;

FIGS. 32A to 32C are a plan view, a cross sectional view, and a perspective view of a composite board 86, respectively;

FIGS. 33A and 33B are perspective views when the composite board 86 and a metal plate 101 are electric resistance welded;

FIGS. 34A to 34C are a plan view, across sectional view, and a perspective view of a composite board 87, respectively;

FIGS. 35A to 35C are a plan view, across sectional view, and a perspective view of a composite board 88, respectively; and

FIGS. 36A and 36B are perspective views when the composite board 88 and a metal plate 121 are electric resistance welded.

### DETAILED DESCRIPTION OF THE PREFERRED EMBODIMENTS

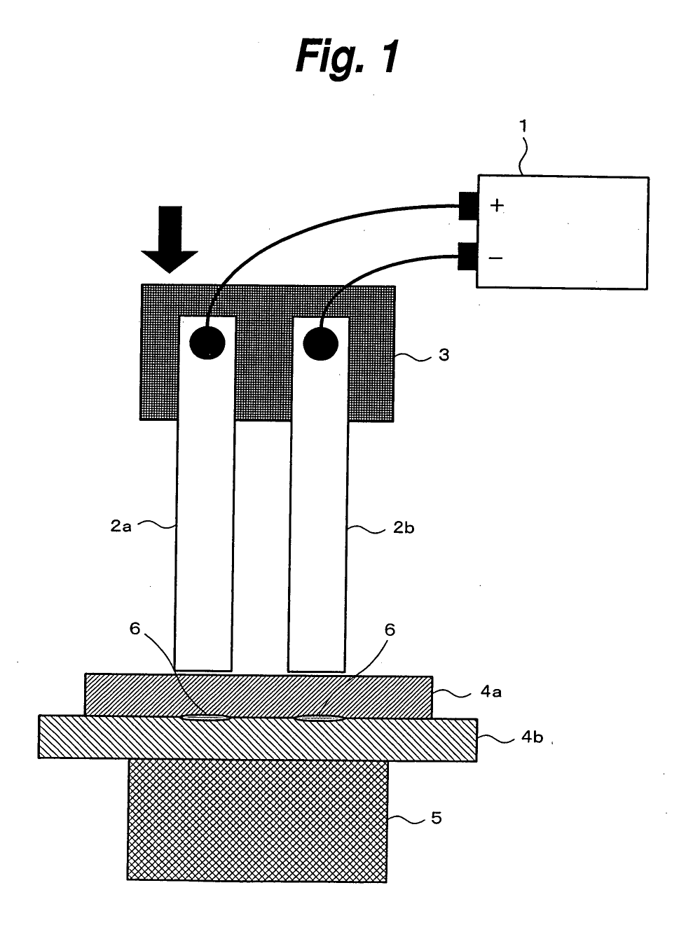

An embodiment of the invention will be described hereinbelow with reference to the drawings. FIG. 1 is a constructional diagram of electric resistance welding according to a general indirect system. Reference numeral 1 denotes an electric resistance welding apparatus. Although not shown, a DC power source apparatus which can supply a voltage of about 5V or less and a current of about 500 A or less is built in the electric resistance welding apparatus 1. Preset voltage and current can be supplied to two welding rods 2a and 2b for a predetermined time by the electric resistance welding apparatus 1. Reference numeral 2a denotes the plus welding rod and 2b indicates the minus welding rod. The two welding rods 2a and 2b are fixed by a welding rod supporting fitting 3. Reference numeral 4a and 4b denote two metal plates as materials to be welded. The metal plates 4a and 4b are put on a metal pedestal 5. The metal pedestal 5 is a metal of a low electric resistance and copper(Cu), copper alloy, silver(Ag), tungsten(W), platinum(Pt), platinum alloy, or the like is used as a material of the metal pedestal 5.

According to the indirect system, the welding rods 2a and 2b are pressed onto the metal plates 4a and 4b to be welded via the welding rod supporting fitting 3 and held in a pressurized state. The current for welding is supplied from the electric resistance welding apparatus 1 in the pressurized state. The half or more of the current which is supplied from the electric resistance welding apparatus 1 flows along the following path. [A plus terminal of the electric resistance welding apparatus 1→welding rod 2a →metal plate 4a →metal plate 4b →metal pedestal 5→metal plate 4b metal plate 4a →welding rod 2b →a minus terminal of the electric resistance welding apparatus 1]

By the large current supplied from the electric resistance welding apparatus 1, heat is generated in joint surfaces 6 of the metal plates 4a and 4b under the welding rods 2a and 2b, a temperature in the joint surfaces 6 rises to high temperature that is equal to or higher than a melting point of the metal, and the metal is fused. After that, the fused joint portions are cooled and solidified, thereby welding the metal plates. The set voltage, set current, set time, and the like of the electric resistance welding apparatus 1 differ depending on shapes, natures, and the like of the welding rods, the electric resistance welding apparatus 1, and the materials to be welded.

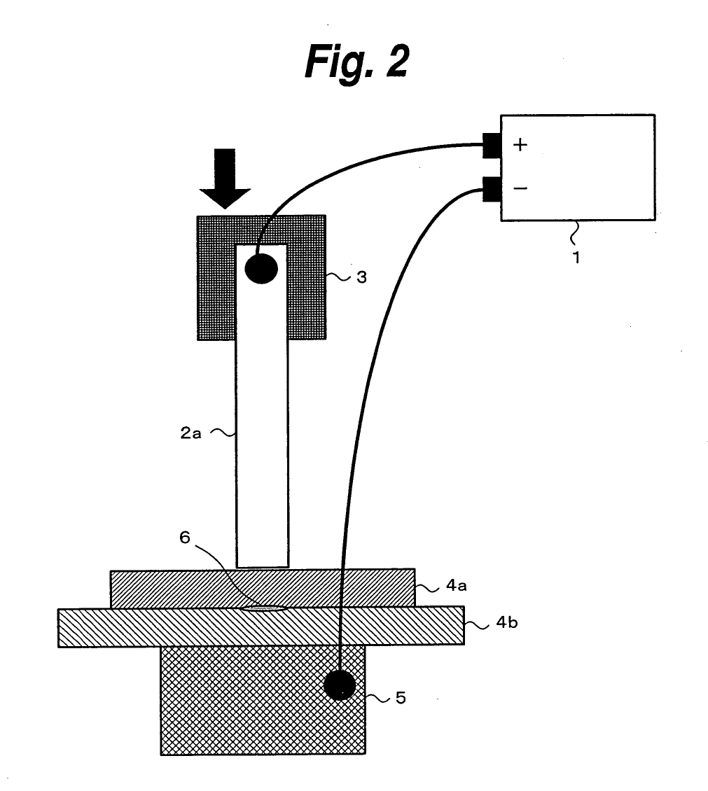

FIG. 2 is a constructional diagram of electric resistance welding according to a general direct system. The half or more of the current which is supplied by the electric resistance welding apparatus 1 flows along the following path. [The plus terminal of the electric resistance welding apparatus 1→welding rod 2a→metal plate 4a→metal plate 4b→metal pedestal 5→minus terminal of the electric resistance welding apparatus 1]

According to the direct system, a constant current relatively larger than that in the foregoing indirect system can be supplied to the welding portion 6. Therefore, even when the metal plates 4a and 4b are thick, the welding of high quality can be performed.

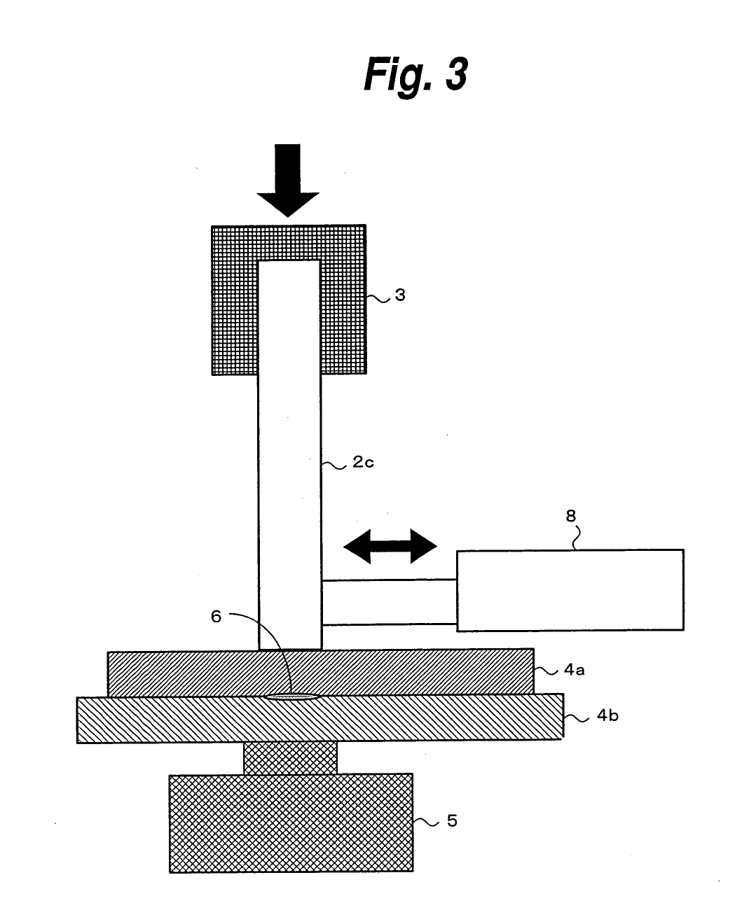

FIG. 3 is a constructional diagram of general ultrasonic welding. A welding rod 2c fixed by the welding rod supporting fitting 3 is vibrated in the lateral direction by a vibration generating apparatus 8. Since the welding rod 2c is pressed downward, large pressure is applied to the metal plates 4a and 4b sandwiched by the welding rod 2c and the pedestal 5. Therefore, in the welding portion 6 under the welding rod 2c, a distance between molecules of the metal plates 4a and 4b is shortened and the molecules are coupled, so that the metal plates are welded. This state is called “solid phase bonding”.

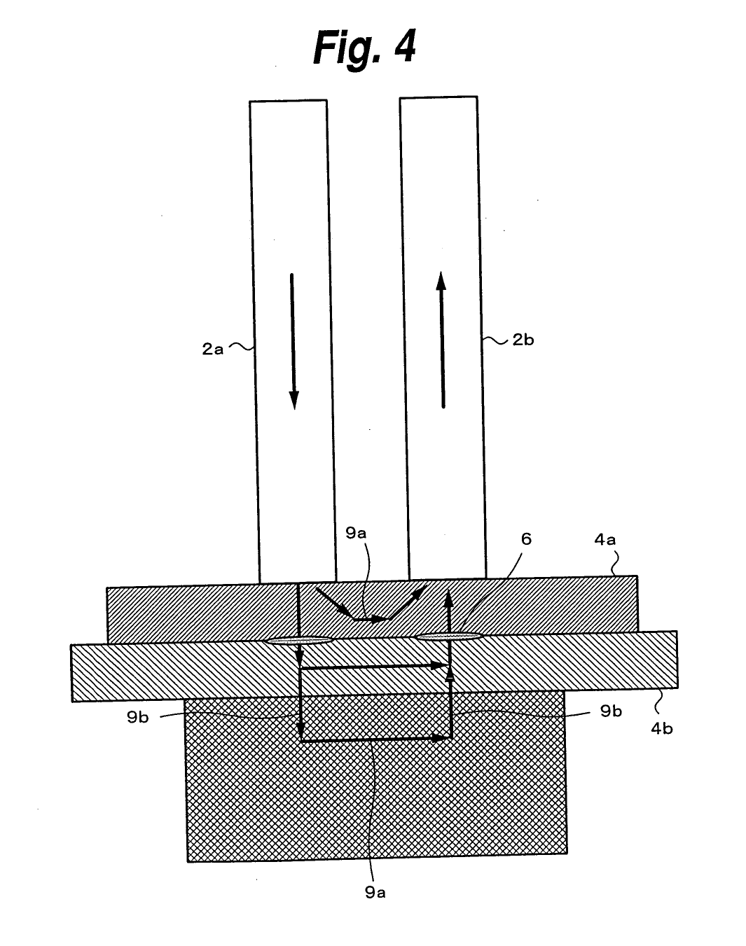

FIG. 4 is a constructional diagram showing a flow of a current at the time of welding metal plates in a flat plate shape. The current supplied from the electric resistance welding apparatus 1 includes a current 9a flowing in the metal plate 4a in the lateral direction. Since the current 9a does not flow in the joint portion 6 of the welding, it is called an invalid current. Since the current flowing in the metal plate 4b flows in the joint portion 6 of the welding portion, it is called an valid current. In the construction shown in FIG. 4, the invalid current of about 20% or more of the current flowing in the welding rod 2a flows.

Since the portions pressed by the welding rods 2a and 2b are pressurized via the metal plates, areas of the pressed portions are not constant but shapes of the pressed portions change every time. Therefore, a variation in welding strength is likely to occur. Thus, when each of the metal plates 4a and 4b as materials to be welded has a thick shape of 0.3 mm or more, it is difficult to weld the metal plates in such a plane shape.

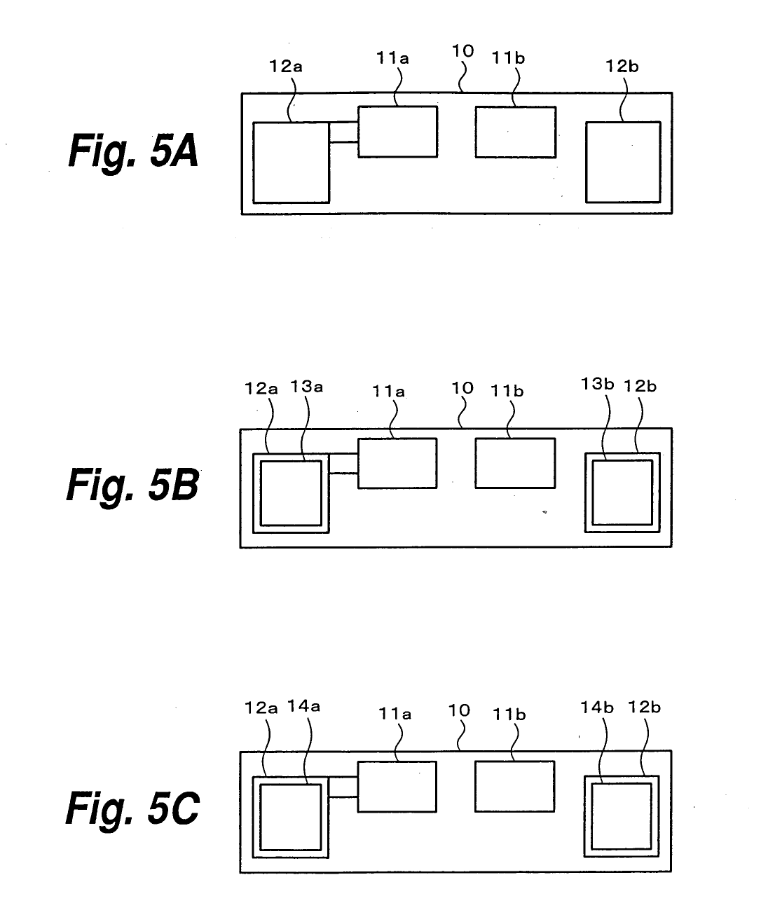

FIG. 5A is a constructional diagram of a circuit board on which a general metal plate is mounted by soldering. Reference numeral 10 denotes a whole circuit board. The circuit board 10 is arranged in a battery pack and connected to a battery and has external terminals 11a and 11b for supplying a charge current and a discharge current. Exposed copper foil lands 12a and 12b in a rectangular shape are arranged at left and right ends of the circuit board 10, respectively.

Cream solders 13a and 13b are arranged on the copper foil lands 12a and 12b as shown in FIG. 5B. Metal plates 14a and 14b are arranged on the cream solders 13a and 13b as shown in FIG. 5C. Those two metal plates are electrically and mechanically coupled with the copper foil lands 12a and 12b. Although not shown, thin gold(Au) leaf is arranged on the copper foil lands on the plus external terminal 11a and the minus external terminal 11b, respectively. This is because electrolytic gold plating or electroless gold plating (evaporation deposition) is performed onto the copper foil lands 12a and 12b. The metal plate 14a and the external terminal 11a of the left side are electrically connected by the copper foil pattern. The metal plate 14b and the external terminal 11b of the right side are electrically connected by the copper foil pattern and a switching device such as a field effect transistor (FET) or the like.

An example of manufacturing steps of the metal plate mounted circuit board as shown in FIGS. 5A to 5C will now be described. Surfaces of the rectangular copper foil lands at the left and right ends of the circuit board which is formed by adhering thin copper foils onto a glass epoxy plate are coated with cream solders in a cream state of high viscosity, respectively. In this instance, there is a manufacturing method whereby a punched thin metal (metal mask) is put on the circuit board, cream solder is put on the whole metal mask, the cream solder is wiped off with a flat knife, and the metal mask is removed, thereby printing the cream solder. Subsequently, the metal plate is put onto the cream solder. The circuit board is put into a reflow furnace of high temperature and heated to high temperature. The temperature at this time is set to about 220 to 230° C. Innumerable small metals of a low melting point in the cream solder are fused and changed from a solid state to a liquid state. An alloy layer is formed between the copper foil of the circuit board and the metal of the low melting point, thereby coupling them. An alloy layer is formed between the metal plate and the metal of the low melting point, thereby coupling them. Thus, the copper foil of the circuit board and the metal plate are electrically and mechanically connected.

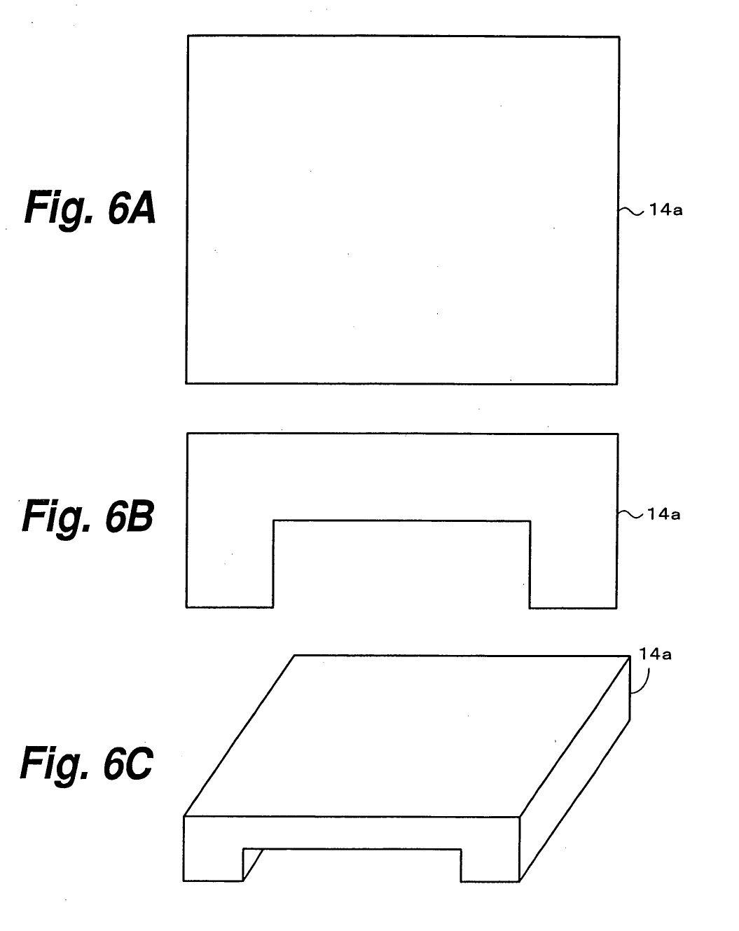

FIGS. 6A to 6C are a plan view, a cross sectional view, and a perspective view of the metal plate 14a, respectively. The metal plate 14a has a concave cross sectional view. The metal plate 14a is made of a material such as nickel or the like having excellent electric resistance weldability in order to perform the electric resistance welding. According to nickel(Ni), heat is more difficult to be diffused at the time of the welding heating than that in the case of copper. Electric volume resistivity is smaller, viscosity is higher, and it is more difficult to be scattered to the periphery at the time of the electric resistance welding than that in the case of iron(Fe). Further, since nickel is difficult to rust, it enables a large current to stably flow at the time of the electric resistance welding. Therefore, nickel is preferable as a metal which is laminated onto an upper layer of a composite board not only in the case of the metal plate 14a.

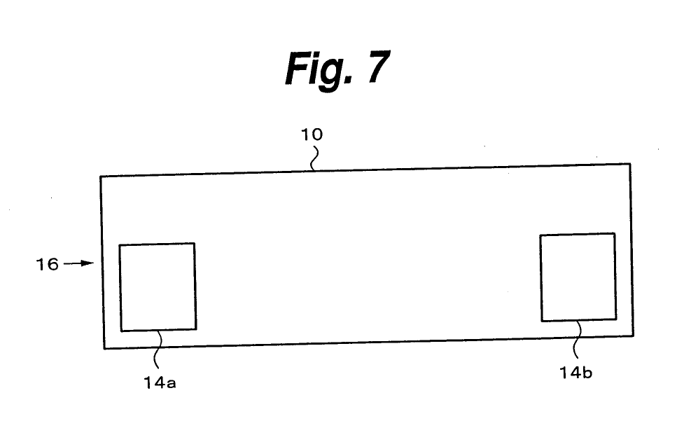

FIG. 7 is a diagram of the circuit board 10 on which the metal plates 14a and 14b are mounted.

FIG. 8 is a constructional diagram in which metal plates 15a and 15b of electrodes are connected to the circuit board 10 on which the general metal plates are mounted. The metal plate 15a of a plus electrode of a battery (for example, lithium polymer battery) is electric resistance welded to the metal plate 14a of the circuit board 10. The metal plate 15a is, for example, an aluminum(Al) metal of about 0.1 mm. By making, for example, external terminals of an electronic device such as a cellular phone or the like come into contact with the external terminals 11a and 11b of the circuit board 10, a discharge can be made from a battery pack.

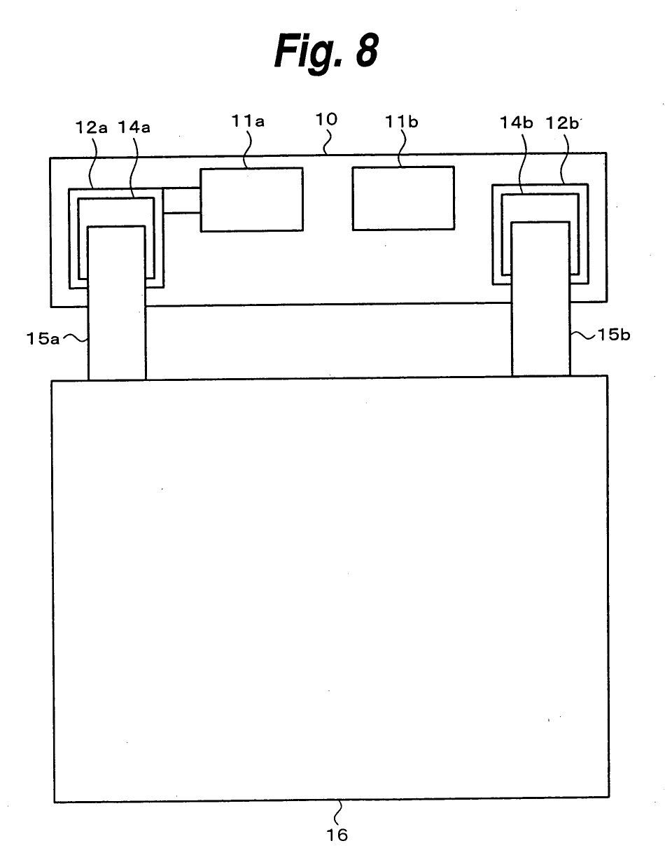

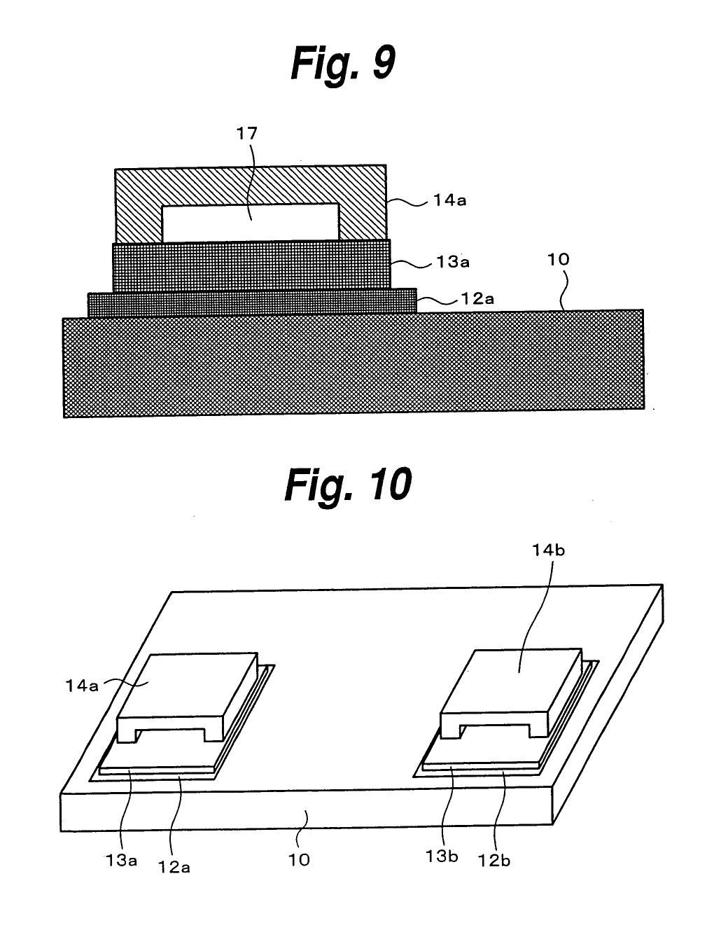

FIG. 9 is across sectional view seen in a direction 16 in FIG. 7 when the metal plate 14a is mounted on the circuit board 10. The copper foil 12a is adhered to an insulative plate (glass epoxy plate) of the circuit board 10. The metal 13a of the low melting point is arranged on the copper foil 12a and bonded thereto. The metal 13a of the low melting point is adhered to both ends of the metal plate 14a. Since the metal is fused by the current and bonded, an alloy layer is formed between the metal plate 14a and the metal 13a of the low melting point and an alloy layer is formed between the metal 13a of the low melting point and the copper foil 12a, respectively. A space (air) exists in a portion 17 surrounded by both ends of the metal plate 14a and the metal 13a of the low melting point and the metal of the low melting point is not bonded there.

FIG. 10 is a perspective view when the metal plates 14a and 14b are mounted on the circuit board 10. The two metal plates and the circuit board 10 are bonded by the metal 13a or 13b of the low melting point. Although the metal of the low melting point (solder) is used in the embodiment, a conductive adhesive agent can be also used.

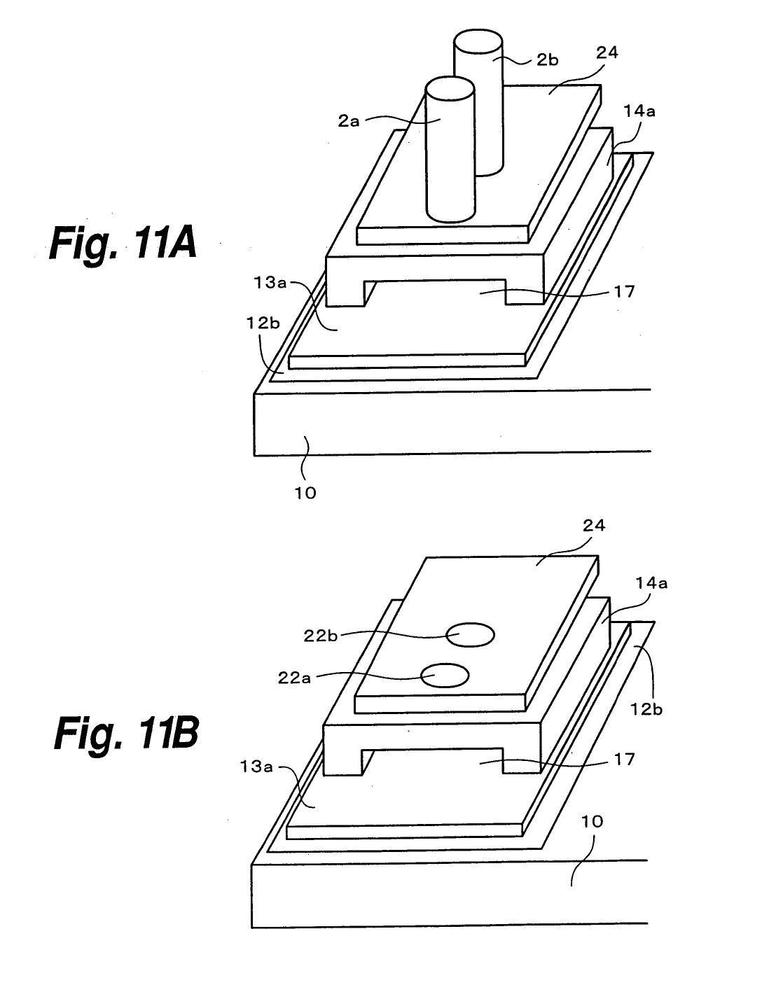

FIGS. 11A and 11B are perspective views when the metal plate 14a and another metal plate 24 are electric resistance welded. The metal plate 24 is arranged on the metal plate 14a. The plus resistance welding rod 2a and the minus resistance welding rod 2b are adhered to the metal plate 24. Both of the resistance welding rods are pressed downward. By supplying a large current to the two resistance welding rods, the metal plate 14a and the metal plate 24 are bonded. The principle in this case has already been described above.

The large current flows in a lower portion 22a of the resistance welding rod 2a and a lower portion 22b of the resistance welding rod 2b upon electric resistance welding and the lower portions are heated to high temperature which is equal to or higher than the melting points of the metal plates 14a and 24. At this time, since the space 17 exists between the resistance welding portions 22a and 22b and the solder 13a, heat conductivity between the resistance welding portions 22a and 22b and the solder is extremely low and the high temperature in the resistance welding portions does not reach the solder 13a under the metal plate. Therefore, such an inconvenience that upon electric resistance welding, the solder is fused or evaporated and vaporized and bonding strength of the metal plate 14a and the solder 13a decreases is avoided. Such an inconvenience that the fused solder is dispersed like particles to the periphery, solder balls are formed, and a defective contact and short-circuit of electronic parts occur is also avoided.

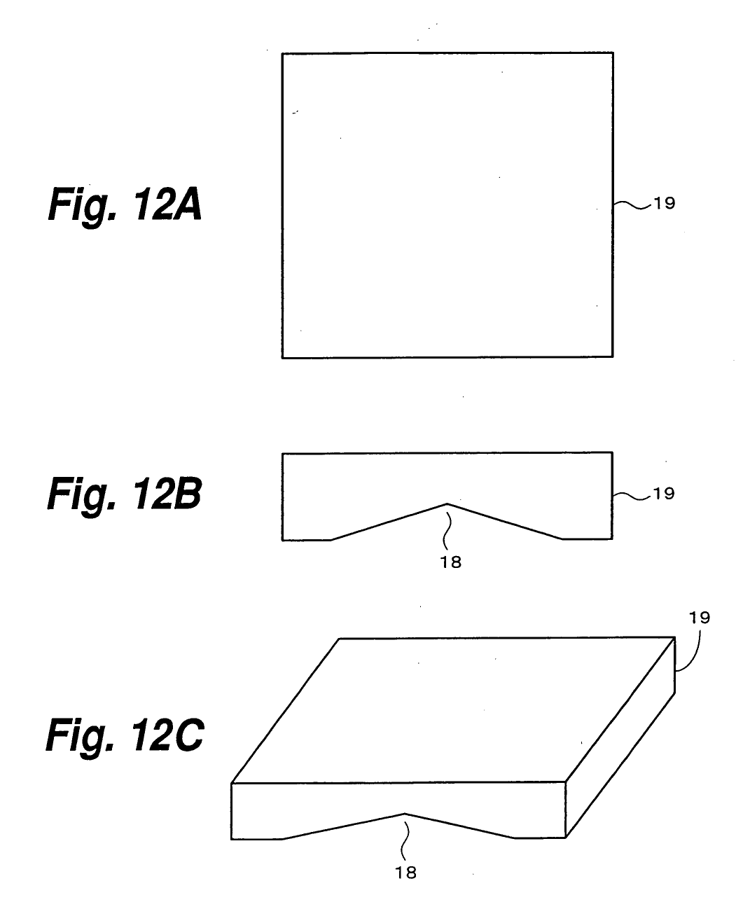

The resistance welding rods 2a and 2b are pressed downward as mentioned above. Therefore, if large pressure is applied to the metal plate 14a, there is a possibility that the metal plate 14a is deformed. It is necessary to thicken the whole metal plate 14a. A plate obtained by further improving the shape of the metal plate 14a for this purpose is a metal plate 19 shown in FIGS. 12A to 12C. FIGS. 12A to 12C are a plan view, a cross sectional view, and a perspective view of the metal plate 19, respectively.

A triangular concave portion 18 is formed in a lower portion of the metal plate 19. Therefore, since heat is also insulated by the air existing in the triangular concave portion 18 upon electric resistance welding, the solder is not fused and the solder balls or the like are not formed. Since a volume of the concave portion 18 of the metal plate 19 is smaller than that of the concave portion 17 of the metal plate 14a, the metal plate 19 is not easily deformed by the electric resistance welding. Thus, the whole thickness of metal plate 19 can be thinned more than in the case of the metal plate 14a.

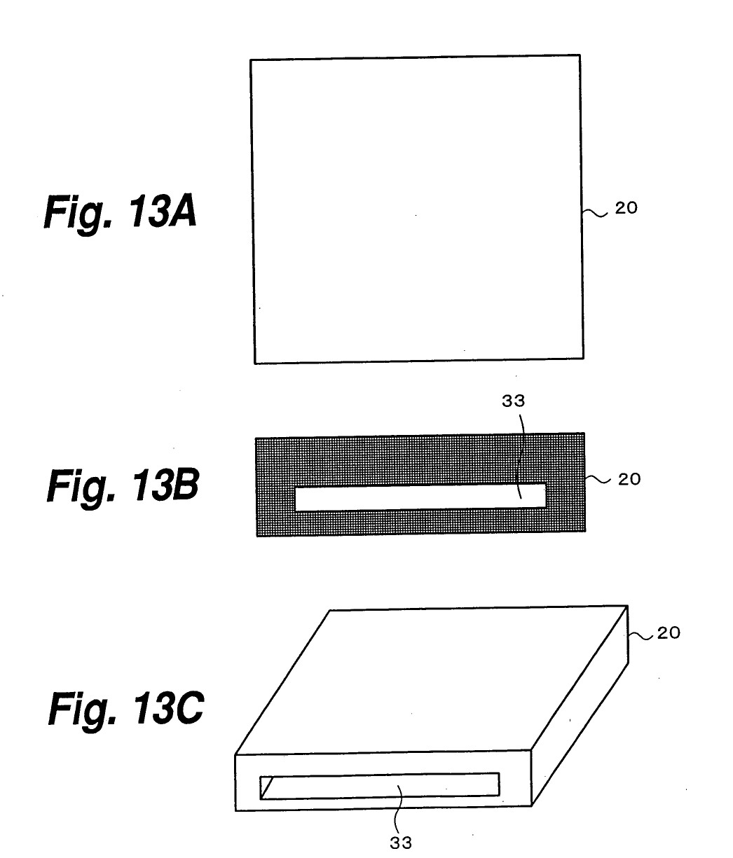

FIGS. 13A to 13C are a plan view, a cross sectional view, and a perspective view of a metal plate 20, respectively. The metal plate 20 has a rectangular space portion 33 at the center. Since heat is insulated by the air existing in the space portion 33 upon electric resistance welding and high temperature in the upper portion of the metal plate 20 does not easily reach the lower portion, the solder in the lower central portion of the metal plate 20 is not fused.

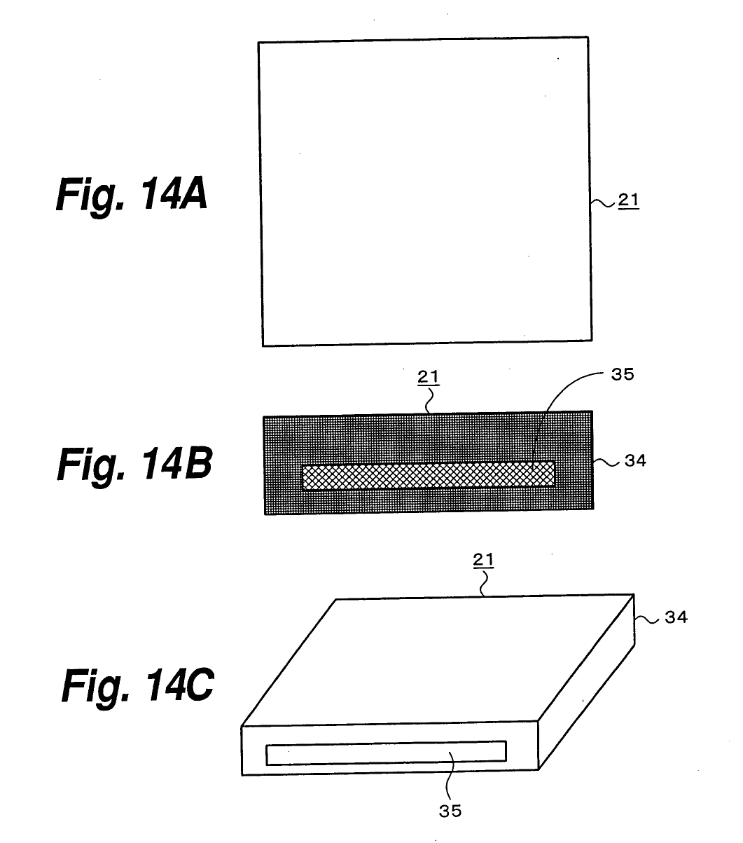

Since the center of the metal plate 20 is the space portion, there is a possibility that the metal plate is deformed when it is pressed with a large force. A composite board 21 is obtained by inserting a rectangular non-metal plate 35 into the space portion 33 as shown in FIGS. 14A to 14C. FIGS. 14A to 14C are a plan view, a cross sectional view, and a perspective view of the composite board 21, respectively. Since the composite board 21 has the non-metal plate of low heat conductivity in the center portion, when the composite board 21 and another metal plate are electric resistance welded, heat is insulated by the rectangular non-metal plate 35, so that high temperature in the upper portion of a metal plate 34 hardly reach the lower portion. The solder which is in contact with the lower central portion of the metal plate 34 is not fused. Since the upper portion and the lower portion of the metal plate 34 are insulated at the center portion of the metal plate 34, the welding current hardly flows into the lower portion. Therefore, heat generation by the welding current is not caused in the lower portion of the metal plate 34.

Further, according to the composite board 21, since the center portion is not a cavity and the rectangular non-metal plate 35 is inserted into the center portion unlike the case of the metal plate 20, the composite board 21 is hardly deformed even by the pressure applied by the electric welding rods or the metal pedestal. Therefore, upon electric resistance welding, the joint surfaces of the electric welding rods 2a and 2b and the metal plate 34 are held in a flat shape, joint areas are wide, and a constant current flows. The joint surfaces of the surface of the metal plate 34 and the surface of another metal plate can be also held in a flat shape.

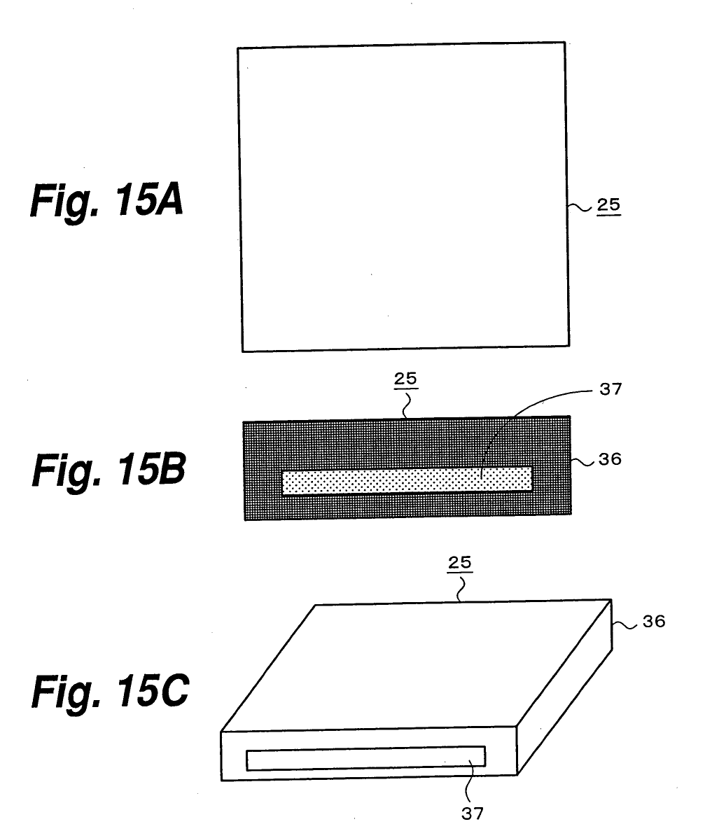

FIGS. 15A to 15C are a plan view, a cross sectional view, and a perspective view of a composite board 25 in which a rectangular metal plate 37 of low heat conductivity is inserted into the space portion 33, respectively. Since heat is insulated by the central metal plate 37 of the low heat conductivity upon electric resistance welding, the high temperature in the upper portion of a metal plate 36 does not easily reach the lower portion. Thus, the solder which is in contact with the lower central portion of the metal plate 36 is not fused.

Generally, a metal of low heat conductivity has a high electric resistance value. Therefore, the upper portion and the lower portion of the metal plate 36 in which the metal plate 37 of the low heat conductivity is inserted are connected by the metal of a relatively large electric resistance and only a small welding current flows in the lower portion of the metal plate 36. Thus, the heat generation by the welding current is small in the lower portion of the metal plate 36.

The following materials can be mentioned as a metal plate of the low heat conductivity.
(1) Lead(Pb) or lead alloy
(2) Iron or iron alloy
(3) Titanium(Ti) or titanium alloy
(4) Tin(Sn) or tin alloy
(5) Nickel alloy

After the surface of the metal plate 37 of the low heat conductivity is oxidized and an electric resistance value of the surface is increased, if the metal plate 37 of the low heat conductivity is inserted into the metal plate 36, a resistance value in the portions from the upper portion to the lower portion of the metal plate 36 increases and the welding current of the lower portion decreases, so that the heat generation of the lower portion of the metal plate 36 upon electric resistance welding can be reduced more.

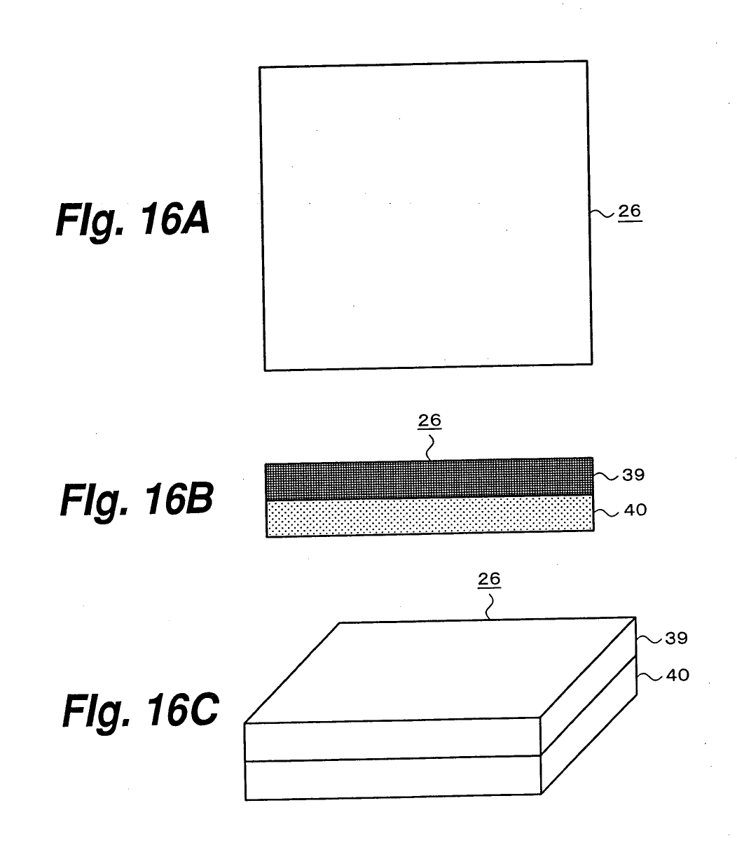

FIGS. 16A to 16C are a plan view, across sectional view, and a perspective view of a composite board 26, respectively. A weldable metal plate 39 having excellent electric resistance weldability is laminated in the upper portion of the composite board 26 and a metal plate 40 of low heat conductivity is laminated in the lower portion. Since heat is insulated to a certain extent by the metal plate 40 of low heat conductivity in the lower portion upon electric resistance welding, high temperature in the upper portion of the weldable metal plate 39 does not easily reach the lower portion, so that the solder which is in contact with the lower portion of the metal plate 40 is not fused. Since an electric resistance of the metal plate 40 of low heat conductivity in the lower portion is relatively large, only a small welding current flows in the lower portion of the composite board 26. Therefore, the heat generation by the welding current is small in the lower portion of the composite board 26.

One of the following methods can be used as a method of bonding two or more kinds of metal plates.

(1) They are bonded by applying a high pressure.

(2) A high-pressure is applied while heating. Since they are bonded by using diffusion of atoms which are produced between the joint surfaces, this method is called a diffusion bonding method.

(3) While keeping the metal plates at high temperature, the two metal plates are sandwiched by two rollers arranged in the upper and lower positions, a high pressure is applied, and they are bonded while being rolled.

(4) A metal block (anvil) is laid on the lower surface and a metal rod is pressed onto the upper surface. While applying pressure, an ultrasonic vibration is applied in the lateral direction.

(5) A metal block (anvil) is laid on the lower surface and a disk-shaped metal is pressed onto the upper surface. While applying pressure, an ultrasonic vibration is applied in the lateral direction, thereby welding. Subsequently, the materials to be welded are slightly moved and the disk-shaped metal is rotated, thereby ultrasonic welding. Finally, the whole linear portion is welded.

(6) A metal plate is laid on the lower surface, two metal rods are pressed onto the upper surface, a large current is supplied to the two metal rods, and joint portions are heated and fused, thereby forming an alloy layer. This method is executed by the electric resistance welding such as spot welding, indirect welding, or the like.

(7) A thick metal plate is laid on the lower surface, one metal rod is pressed onto the upper surface, a large current is supplied to the metal rod and the thick metal plate, and a joint portion is heated and fused, thereby forming an alloy layer. This method is executed by the electric resistance welding such as spot welding, indirect welding, or the like.

(8) A thick metal plate is laid on the lower surface, one rotatable disk-shaped metal is pressed onto the upper surface, a large current is supplied to the disk-shaped metal and the thick metal plate, a joint portion is heated and fused, and an alloy layer is formed, thereby welding. Subsequently, the materials to be welded are slightly moved and the disk-shaped metal is rotated, thereby electric resistance welding. Finally, the whole linear portion is welded. This method is executed by the electric resistance welding such as spot welding, indirect welding, or the like.

(9) A metal of a low melting point is sandwiched between the joint surfaces and heated and an alloy layer is formed, thereby welding.

(10) A metal of a low melting point coated with a flux is sandwiched between joint surfaces and heated and an alloy layer is formed, thereby welding.

(11) A flux and a metal of a low melting point are sandwiched between joint surfaces and heated and an alloy layer is formed, thereby welding.

(12) In a portion where a flat portion of the metal plate A and a hole portion of the metal plate B are overlaid, a flux and a metal of a low melting point are arranged and heated and an alloy layer is formed, thereby welding.

(13) The joint surfaces are coated with a conductive adhesive agent and they are heated and pressed.

(14) The joint surfaces are coated with a conductive adhesive agent and they are pressed.

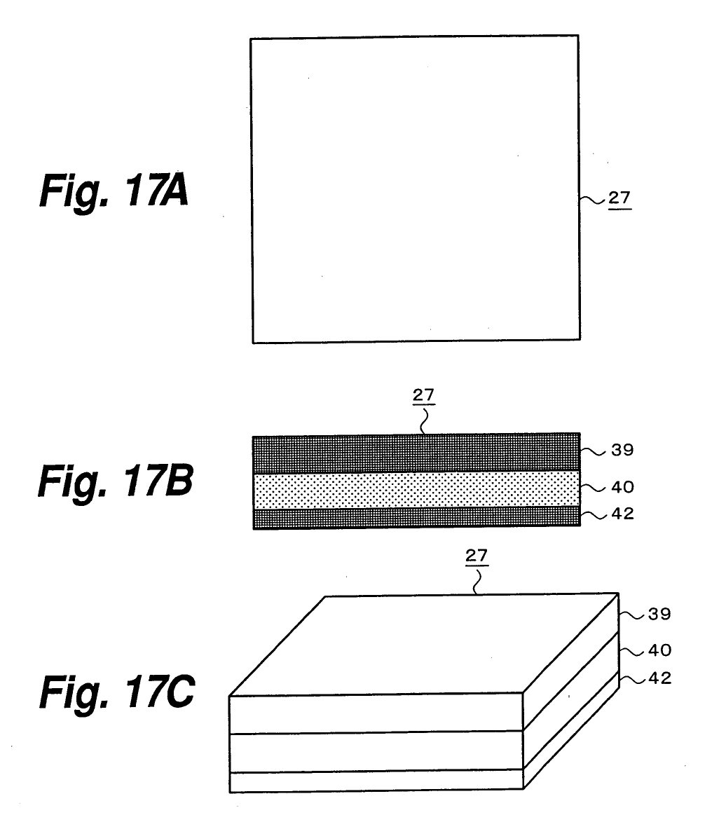

FIGS. 17A to 17C are a plan view, across sectional view, and a perspective view of a composite board 27 obtained by further laminating an anticorrosive metal plate 42 onto the composite board 26 shown in FIGS. 16A to 16C, respectively. The principle that the solder is not fused is the same as that of the composite board 26. When iron is used as a metal plate 40 of the low heat conductivity, since the surface is oxidized and rusts and cannot be soldered, it is necessary to cover the metal plate 40 with the metal which hardly rusts. Therefore, the oxidization of the surface can be prevented by adhering the metal which is hardly oxidized onto the lower surface of the metal plate 40 of the low heat conductivity. For example, nickel, gold, silver, or the like is used as such a kind of anticorrosive metal plate 42.

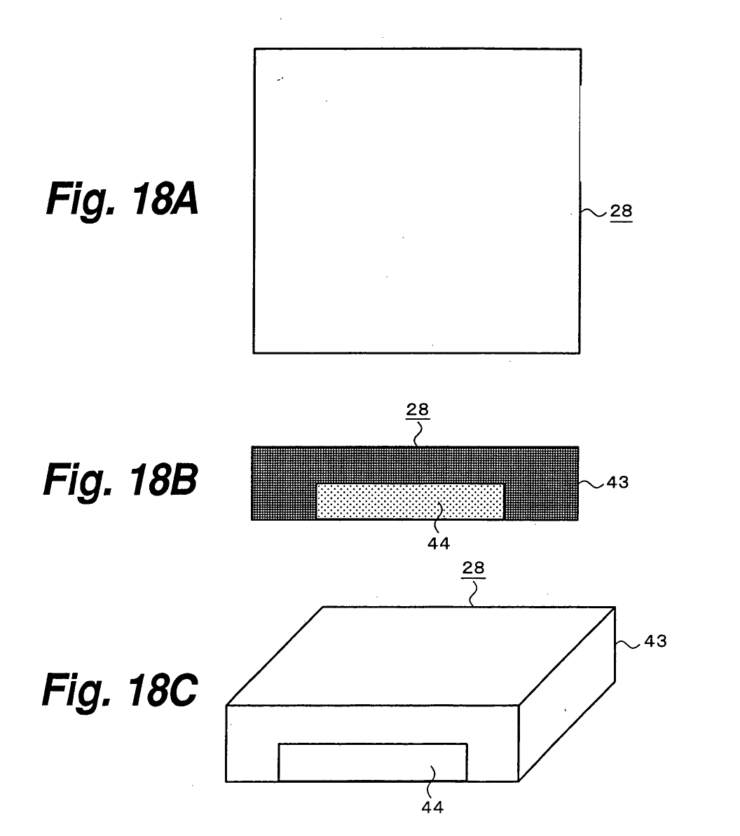

FIGS. 18A to 18C are a plan view, a cross sectional view, and a perspective view of a composite board 28 obtained by bonding a non-metal plate 44 onto a concave portion of a metal plate 43 having excellent electric resistance weldability, respectively. Since materials from the upper portion to both ends of lower edges of the metal plate 43 are made of the same metal, if both ends of the lower portions are connected to the copper foil lands of the circuit board by solder, an electric resistance value of a portion from the upper portion of the metal plate 43 to the copper foil land of the circuit board is reduced. When the electric resistance value is small, a resistance value of the whole battery pack decreases, so that performance is improved. At the time of the electric resistance connection, however, since a large current flows, there is a risk that the lower portion of the metal plate 43 generates heat and the contacting solder is fused. To prevent it, by bonding the non-metal plate 44 to the concave portion and insulating heat, high temperature in the upper portion of the metal plate 43 does not easily reach the lower portion, the solder which is in contact with the lower central portion of the metal plate 43 is not fused. According to such a construction, a thickness of composite board 28 can be relatively thinned.

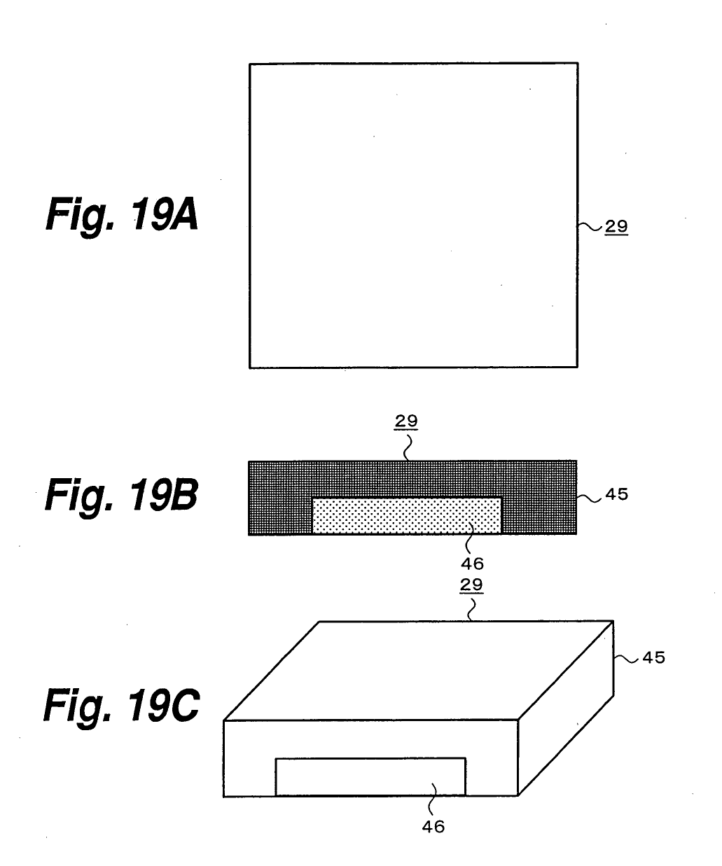

FIGS. 19A to 19C are a plan view, a cross sectional view, and a perspective view of a composite board 29, respectively, which has the same shape as that in FIG. 18A and is obtained by bonding a metal plate 46 of low heat conductivity instead of the non-metal plate 44. Also in this construction, since heat is insulated by the metal plate 46 of the low heat conductivity, high temperature of an upper portion of a metal plate 45 does not easily reach a lower portion, the solder which is in contact with the lower portion of the composite board 29 is not fused.

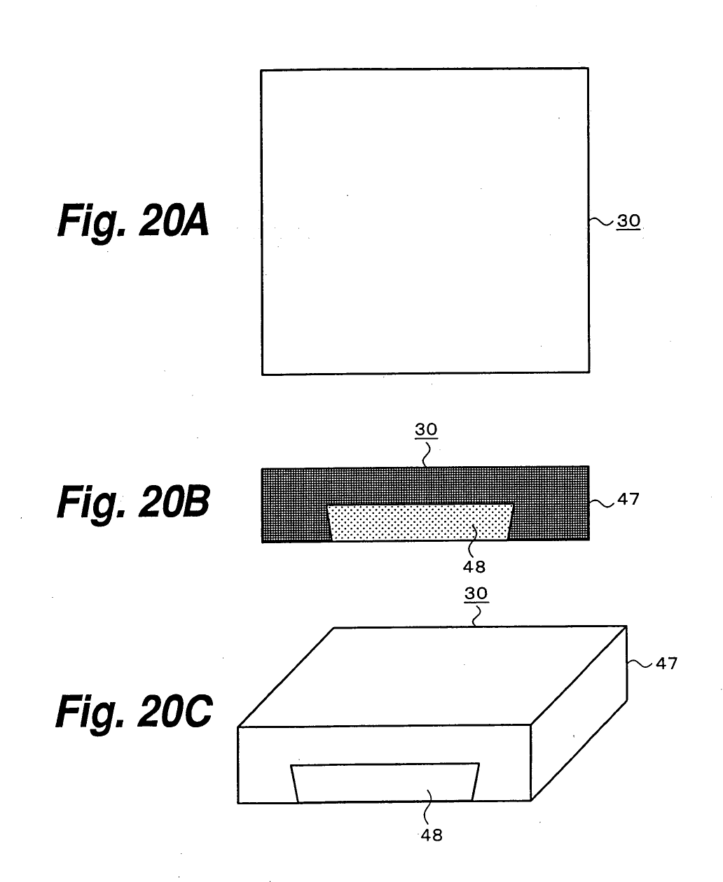

FIGS. 20A to 20C are a plan view, a cross sectional view, and a perspective view of a composite board 30, respectively, in which a tapered concave portion is formed in a lower portion of a weldable metal plate 47 having excellent electric resistance weldability and a non-metal plate 48 whose cross sectional shape is an almost trapezoid is inserted into the concave portion. According to this construction, the non-metal plate 48 is not easily pulled down because it has the tapered shape. The non-metal plate 48 can be fixed into the metal plate 47 even if a joint portion between the metal plate 47 and the non-metal plate 48 is not coated with an adhesive agent.

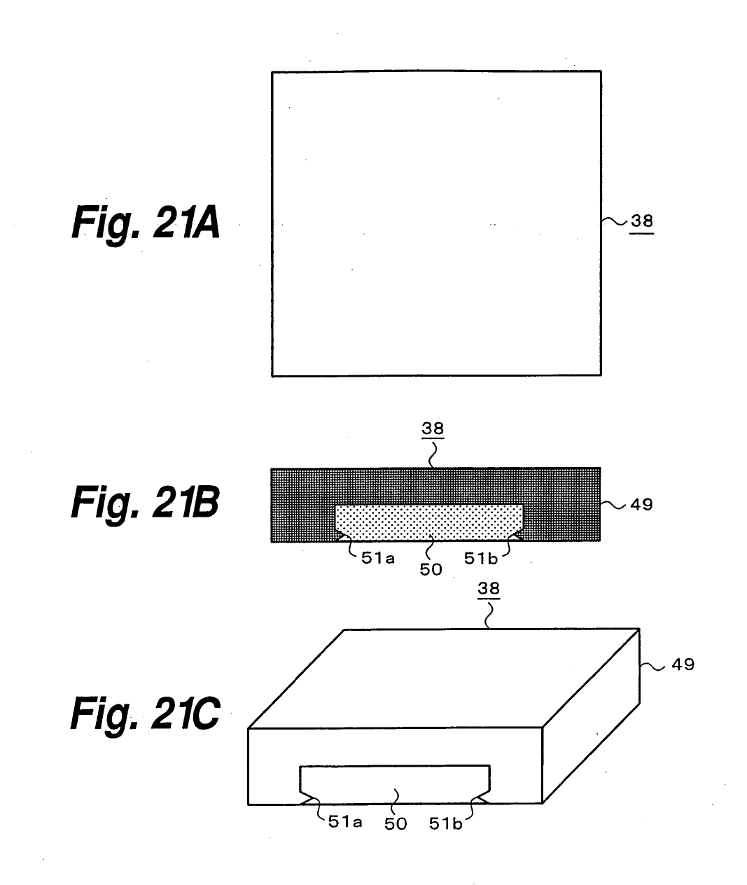

FIGS. 21A to 21C are a plan view, a cross sectional view, and a perspective view of a composite board 38, respectively, in which a concave portion is formed in a lower portion of a weldable metal plate 49 having excellent electric resistance weldability and a non-metal plate 50 whose cross sectional shape is an almost rectangle is inserted into the concave portion. Projections 51a and 51b are formed on the left and right sides of the concave portion. Therefore, the non-metal plate 50 is not easily pulled down and the non-metal plate 50 can be fixed into the weldable metal plate 49 even if a joint portion between the weldable metal plate 49 and the non-metal plate 48 is not coated with an adhesive agent.

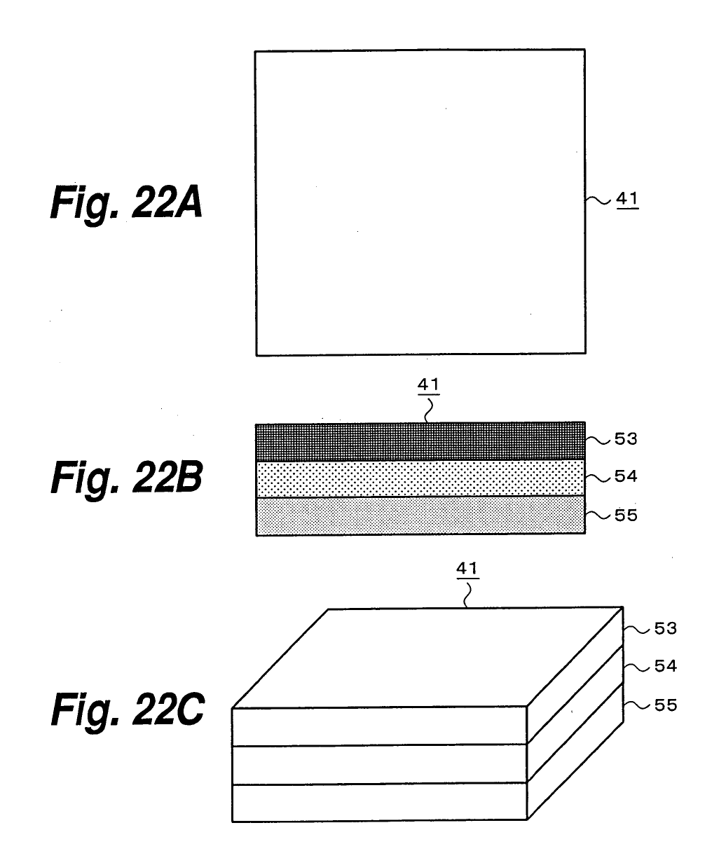

FIGS. 22A to 22C are a plan view, a cross sectional view, and a perspective view of a composite board 41, respectively, in which a weldable metal plate 53 having excellent electric resistance weldability is laminated in an upper layer, a metal plate 54 of low heat conductivity is laminated in an intermediate layer, and a metal plate 55 of high heat conductivity is laminated in a lower layer. For example, copper, silver, or the like is used as a metal plate 55 of the high heat conductivity. According to this construction, since the metal plate 54 of the low heat conductivity is laminated in an intermediate layer, when another metal plate and the composite board 41 are electric resistance welded in an upper central portion, since heat is insulated to a certain extent by the metal plate 54 as an intermediate layer, high temperature in the upper central portion does not easily reach a lower portion of the composite board 41. Therefore, the solder which is in contact with the metal plate 55 is not fused.

Since an electric resistance of the metal plate 54 as an intermediate layer is relatively large, only a small welding current flows in the lower layer at the time of the electric resistance connection. Therefore, heat generation by the welding current is small in the lower portion of the composite board 41. Further, since the metal plate 55 of the high heat conductivity diffuses the high temperature in the electric resistance welding portion to the whole plate, the temperature in the lower portion of the composite board 41 does not rise easily.

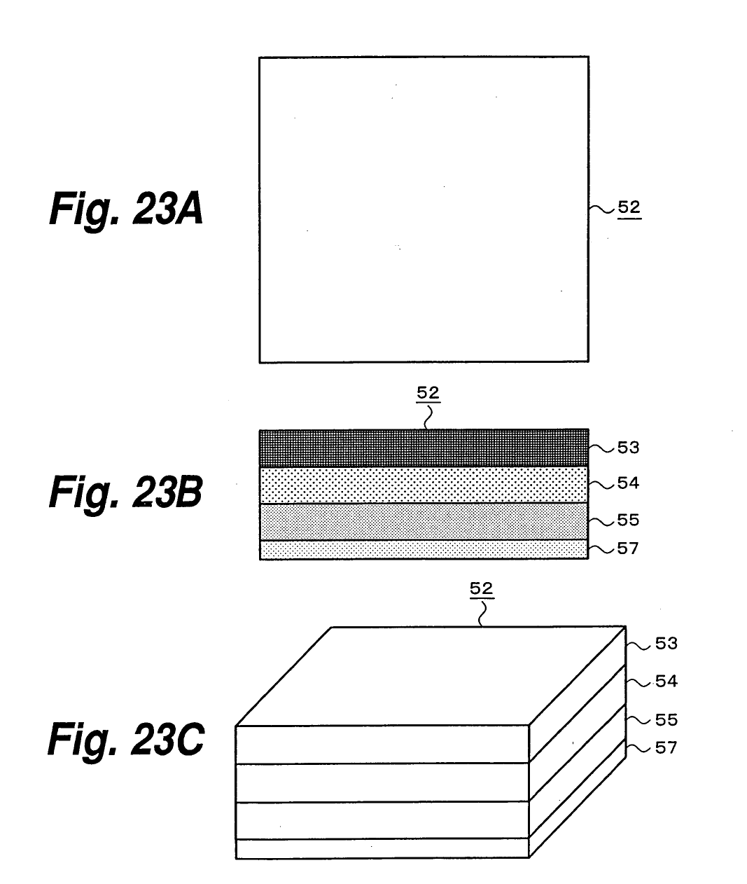

FIGS. 23A to 23C are a plan view, a cross sectional view, and a perspective view of a composite board 52 obtained by bonding an anticorrosive metal plate 57 onto a lower layer, respectively. When, for example, copper or the like is used as a metal plate 55, the surface is oxidized and likely to rust. Therefore, there is a risk of occurrence of defective soldering. To prevent it, by bonding the anticorrosive metal plate 57, the composite board 52 is made difficult to rust, thereby enabling solderability to be improved.

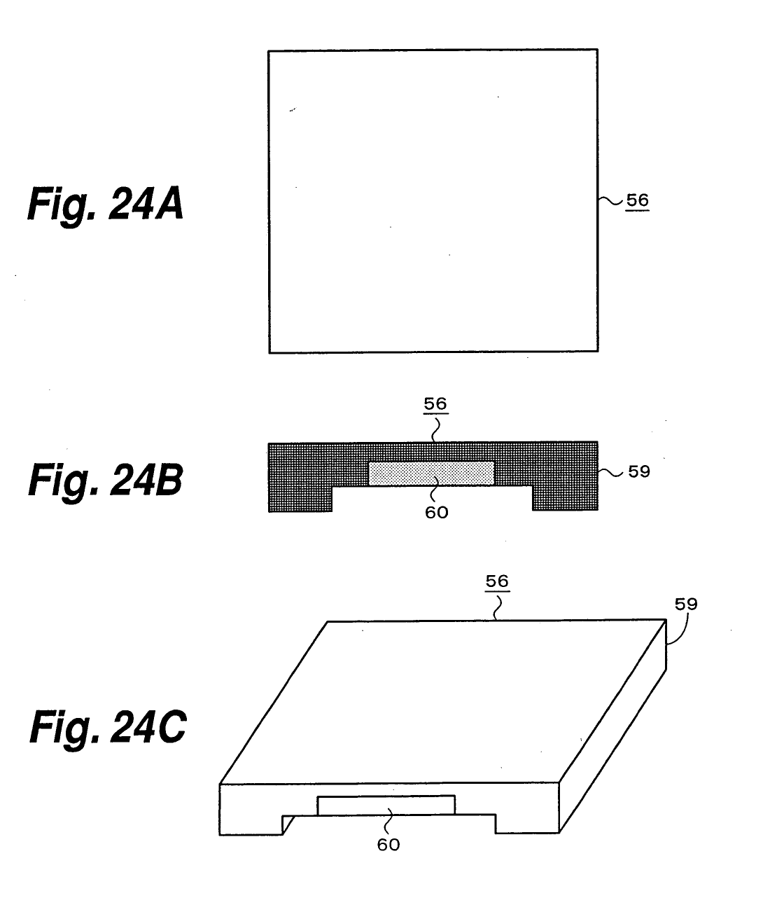

FIGS. 24A to 24C are a plan view, across sectional view, and a perspective view of a composite board 56 obtained by bonding a concave weldable metal plate 59 having excellent electric resistance weldability and a metal plate 60 of a low resistance, respectively. A large welding current flows in the low resistance metal plate 60 upon electric resistance welding. Since a resistance of the low-resistance metal plate 60 is smaller than that of the weldable metal plate 59, the low-resistance metal plate 60 can allow a larger welding current to flow. As mentioned above, there is such an effect that the low-resistance metal plate 60 can allow the larger welding current to flow in the welding portion. Since the space exists in the lower portion of the low-resistance metal plate 60, high temperature upon electric resistance welding does not reach the solder in the lower portion and the solder is not fused.

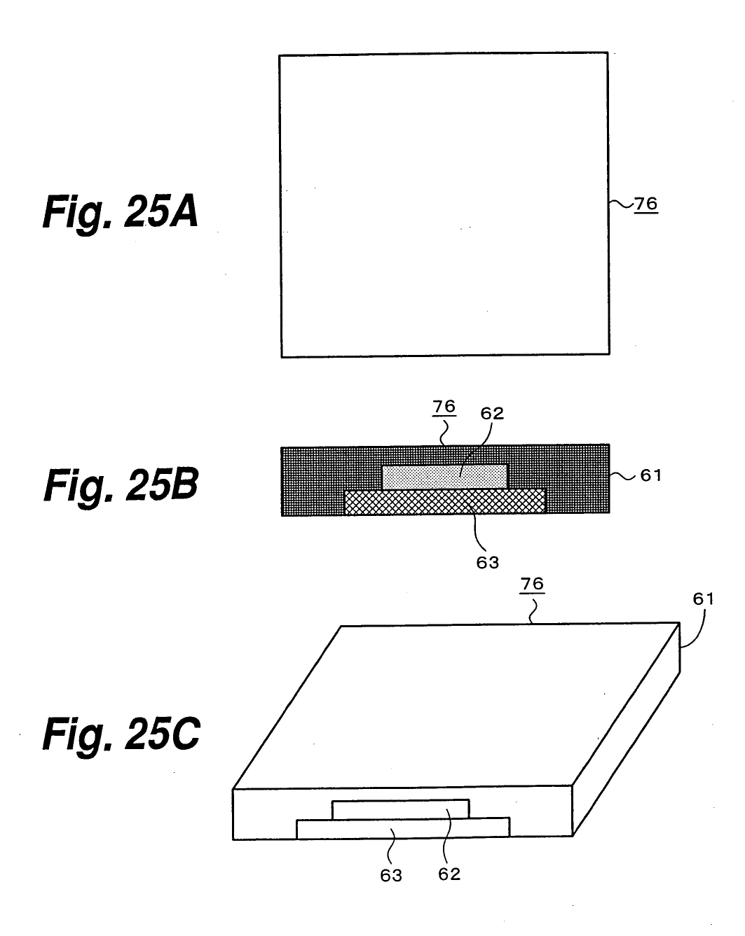

FIGS. 25A to 25C are a plan view, a cross sectional view, and a perspective view of a composite board 76 obtained by bonding a concave weldable metal plate 61 having excellent electric resistance weldability, a metal plate 62 of a low resistance, and a non-metal plate 63, respectively. A large welding current flows in the low resistance metal plate 62 upon electric resistance welding. Since a resistance of the low-resistance metal plate 62 is smaller than that of the weldable metal plate 61, the low-resistance metal plate 62 can allow a larger welding current to flow. As mentioned above, there is such an effect that the low-resistance metal plate 62 can allow the larger welding current to flow in the welding portion. Since the non-metal plate 63 of the low heat conductivity exists in the lower portion of the low-resistance metal plate 62, high temperature upon electric resistance welding does not reach the solder under the metal plate.

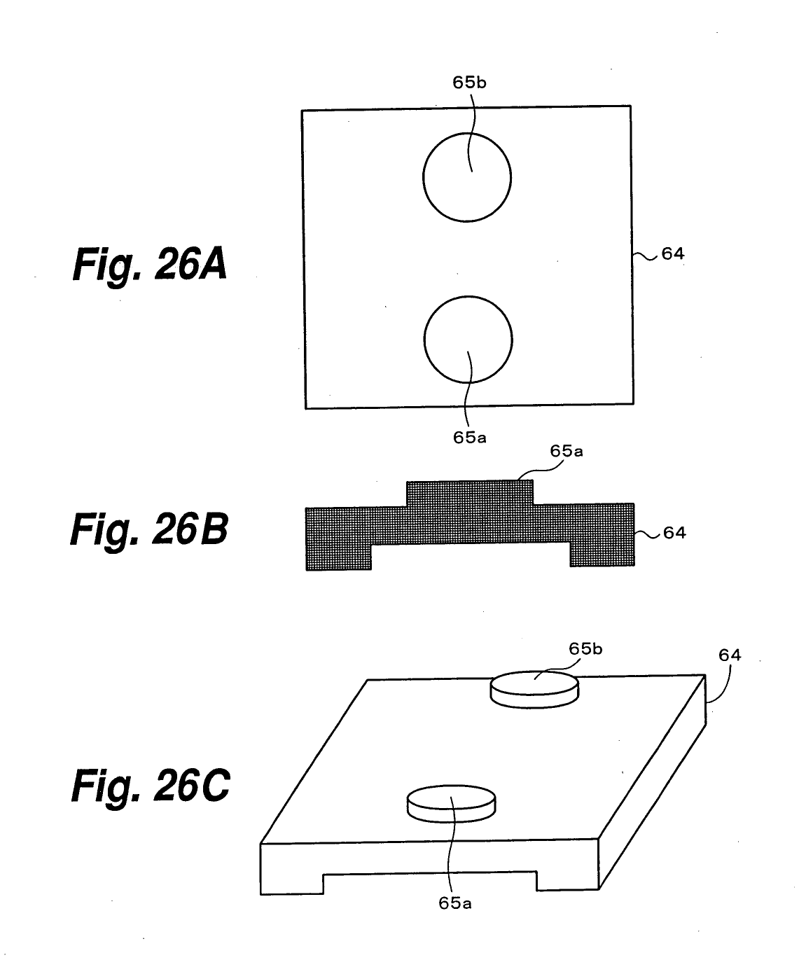

FIGS. 26A to 26C are a plan view, a cross sectional view, and a perspective view of a weldable metal plate 64 having excellent electric resistance weldability in which a lower portion has a concave shape and two convex portions 65a and 65b are formed in an upper portion, respectively. Upon electric resistance welding, electric resistance welding rods are arranged in positions above the two cylindrical convex portions 65a and 65b and a welding current is supplied. Thus, the welding current flows in the convex portions 65a and 65b. Since a joint area of the metal plate 64 and another metal plate which is welded to the metal plate 64 is held constant, they can be electric resistance connected while supplying the predetermined welding current.

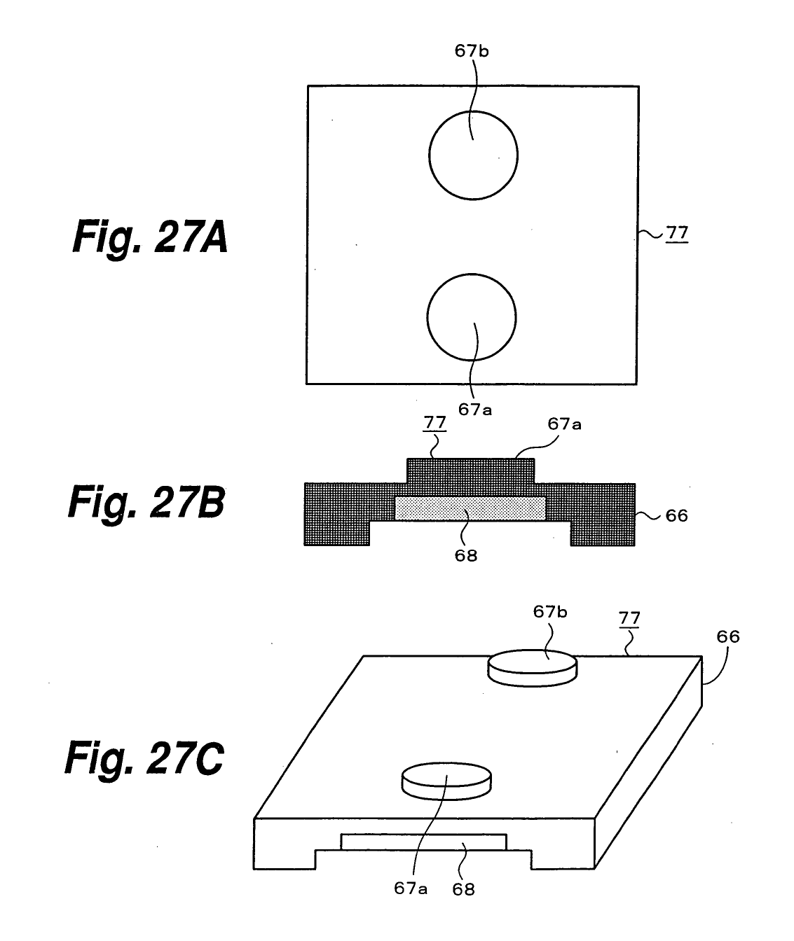

FIGS. 27A to 27C are a plan view, across sectional view, and a perspective view of a composite board 77 obtained by bonding a weldable metal plate 66 having excellent electric resistance weldability in that a lower portion has a concave shape and two convex portions 67a and 67b are formed, in an upper portion and a metal plate 68 of a low resistance, respectively. By bonding the metal plate 68 of the low resistance, a larger welding current can be supplied in a welding portion upon electric resistance welding.

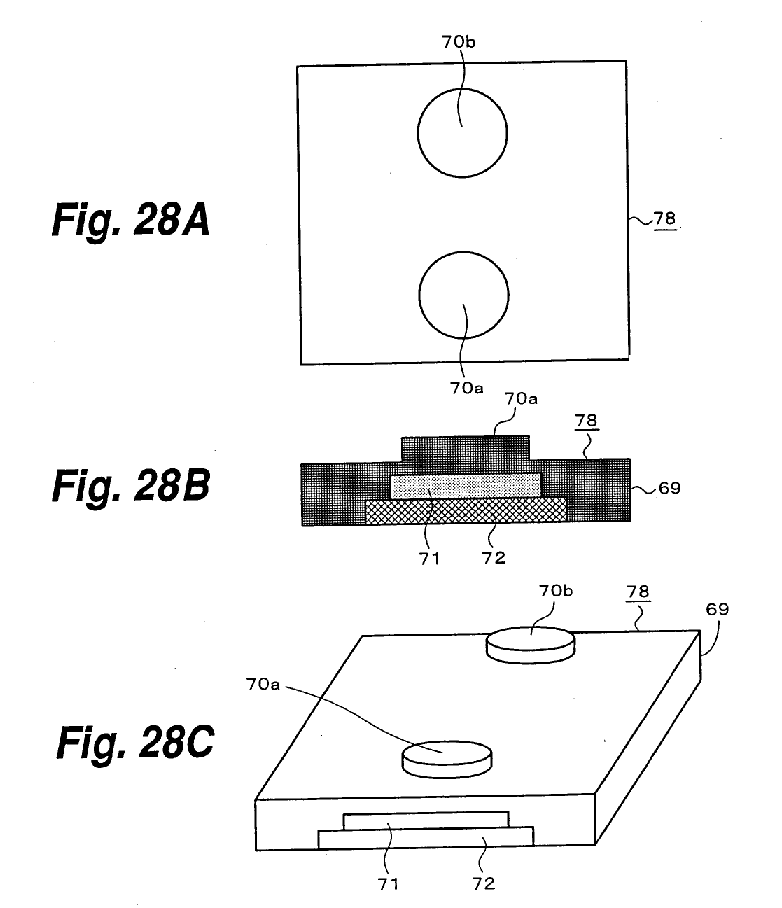

FIGS. 28A to 28C are a plan view, a cross sectional view, and a perspective view of a composite board 78 obtained by bonding a weldable metal plate 69 having excellent electric resistance weldability in that a lower portion has a concave shape and two convex portions 70a and 70b are formed in an upper portion, a metal plate 71 of a low resistance, and a non-metal plate 72, respectively. When comparing with FIG. 27B, the non-metal plate 72 is newly bonded. Thus, even if large pressure is applied upon electric resistance welding, since the composite board 78 is supported by the non-metal plate 72, it is possible to prevent the composite board 78 from being deformed.

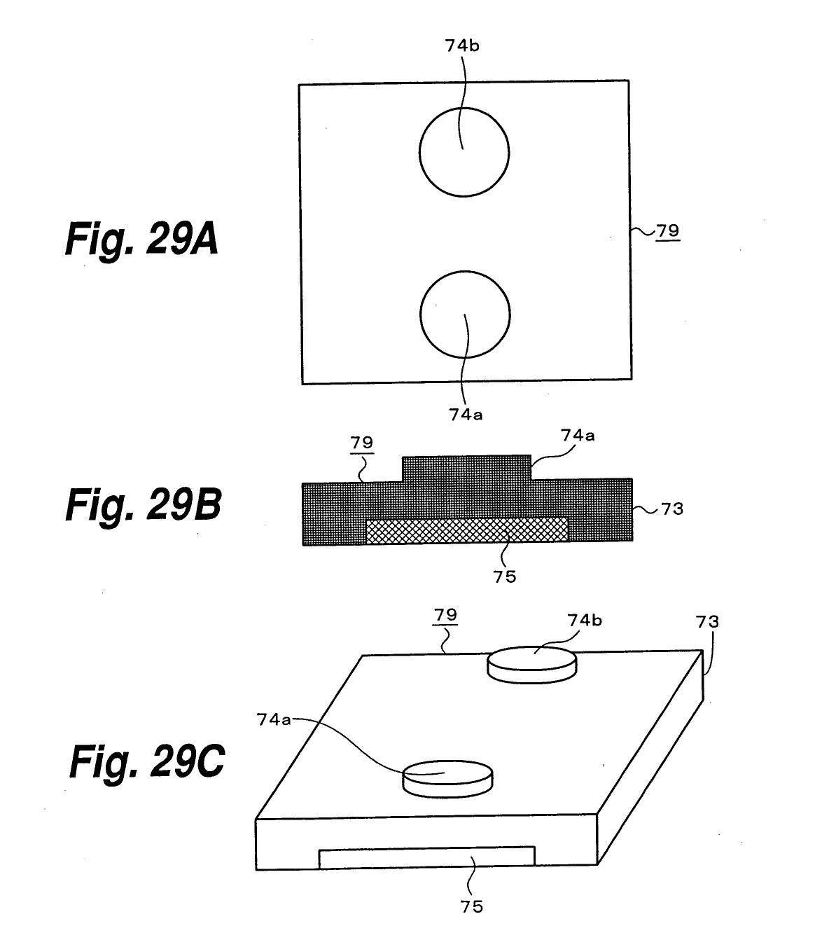

FIGS. 29A to 29C are a plan view, a cross sectional view, and a perspective view of a composite board 79 obtained by bonding a weldable metal plate 73 having excellent electric resistance weldability in that a lower portion has a concave shape and two convex portions 74a and 74b are formed in an upper portion and a non-metal plate 75, respectively. According to the construction of such a metal plate, even if large pressure is applied upon electric resistance welding, since the composite board 79 is supported by the non-metal plate 75, the metal plate 73 is not deformed. Since the composite board 79 has the non-metal plate 75 of low heat conductivity in the lower portion, when it is electric resistance welded to another metal plate in the upper central portion of the composite board 79, heat is insulated by the non-metal plate 75 in the lower portion. Therefore, since high temperature in the upper central portion does not easily reach the lower portion, the solder which is in contact with the non-metal plate 75 is not fused.

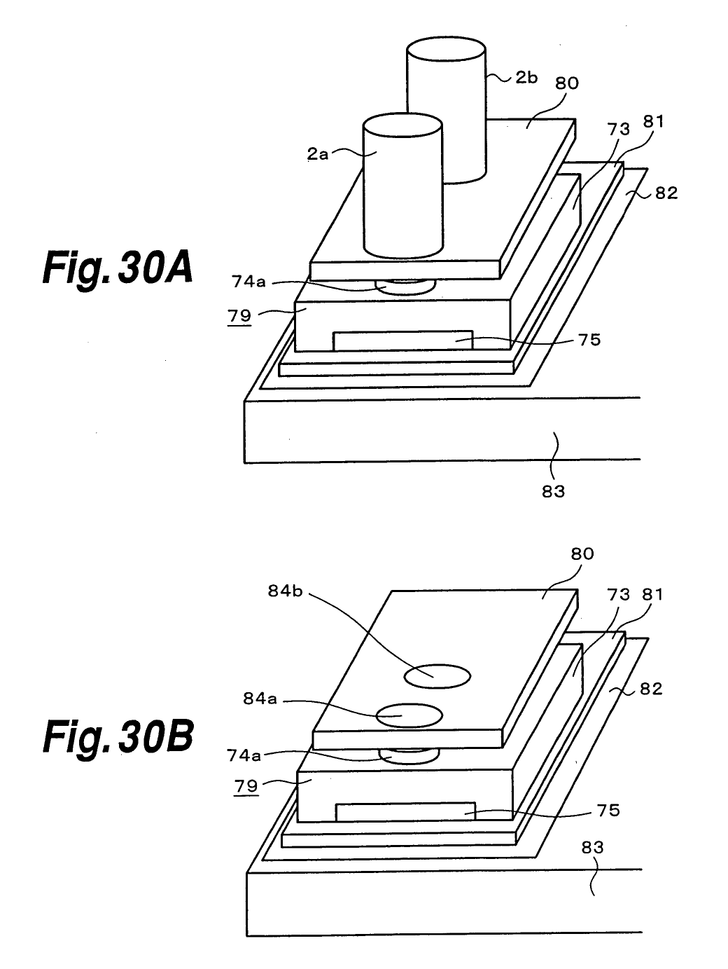

FIGS. 30A and 30B are perspective views when the composite board 79 shown in FIG. 29C and another metal plate 80 are electric resistance welded. The metal plate 80 is arranged on the composite board 79. The plus resistance welding rod 2a and the minus resistance welding rod 2b are arranged on the metal plate 80. The resistance welding rods 2a and 2b are pressed downward. In this construction, when electric resistance welding is performed and a large current is supplied to the resistance welding rods 2a and 2b, the composite board 79 and the metal plate 80 are bonded. Upon electric resistance welding, the large current flows in resistance welding portions under the resistance welding rods 2a and 2b and the resistance welding portions are heated to high temperature that is equal to or higher than melting points of the metal plates 73 and 80. At this time, since the non-metal plate 75 of the low heat conductivity is arranged between the resistance welding portions and solder 81, heat conductivity between the resistance welding portions and the solder 81 is extremely low, so that high temperature in the resistance welding portions does not reach the solder 81 in the lower portion. Therefore, such an inconvenience that upon electric resistance welding, the solder is fused or evaporated and vaporized and bonding strength of the metal plate 80 and a circuit board 83 decreases, or the like does not occur. Such an inconvenience that the solder is fused and scatters to the periphery, solder balls are deposited to electronic parts of the circuit board, and a short-circuit is caused does not occur, either.

Upon electric resistance welding of the composite board 79 and the metal plate 80, the electric resistance welding rods are arranged in the positions above the two cylindrical convex portions 74a and 74b and a welding current is supplied. Thus, the welding current flows in the two cylindrical convex portions 74a and 74b. Since a joint area of the metal plates 73 and 80 is held constant, they can be electric resistance welded while the predetermined welding current is supplied. In the composite board 79 in such a shape, even when pressure which is applied upon electric resistance welding is large, since the composite board 79 is supported by the non-metal plate 75, there is no possibility that the center portion of the composite board 79 is crushed and deformed.

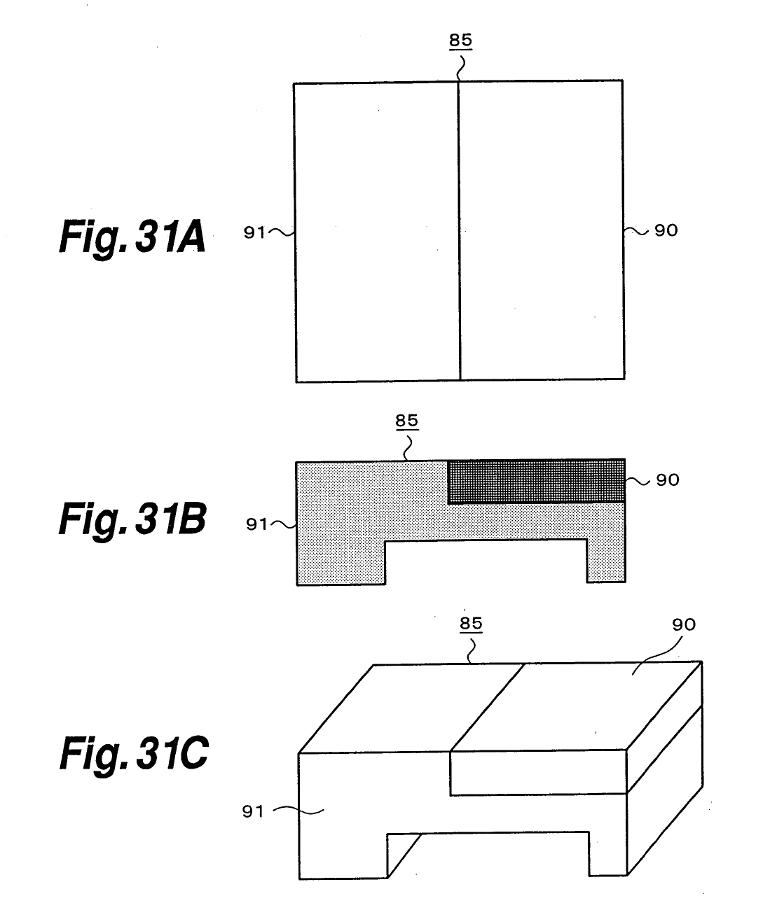

FIGS. 31A to 31C are a plan view, across sectional view, and a perspective view of a composite board 85 obtained by bonding a weldable metal plate 90 having excellent electric resistance weldability and a metal plate 91 of a low resistance, respectively. Concave portions are formed in a right upper portion and a right lower central portion of the metal plate 91 of the low resistance. The weldable metal plate 90 is bonded to the concave portion in the right upper portion of the metal plate 91 of the low resistance. Since the concave portion is formed in the right lower central portion of the metal plate 91 and a space (air) exists there, when the metal plate 91 and another metal plate are electric resistance welded in the right upper central portion of the metal plate 90, high temperature in the welding portion is insulated by the air, high temperature in the upper central portion does not easily reach the lower portion. Thus, the solder under the right lower central portion is not fused. Since 60% or more of the composite board 85 is constructed by the metal plate 91 of the low resistance, a resistance value in a region from the welding portion in the upper portion of the metal plate 91 to the lower portion thereof is small.

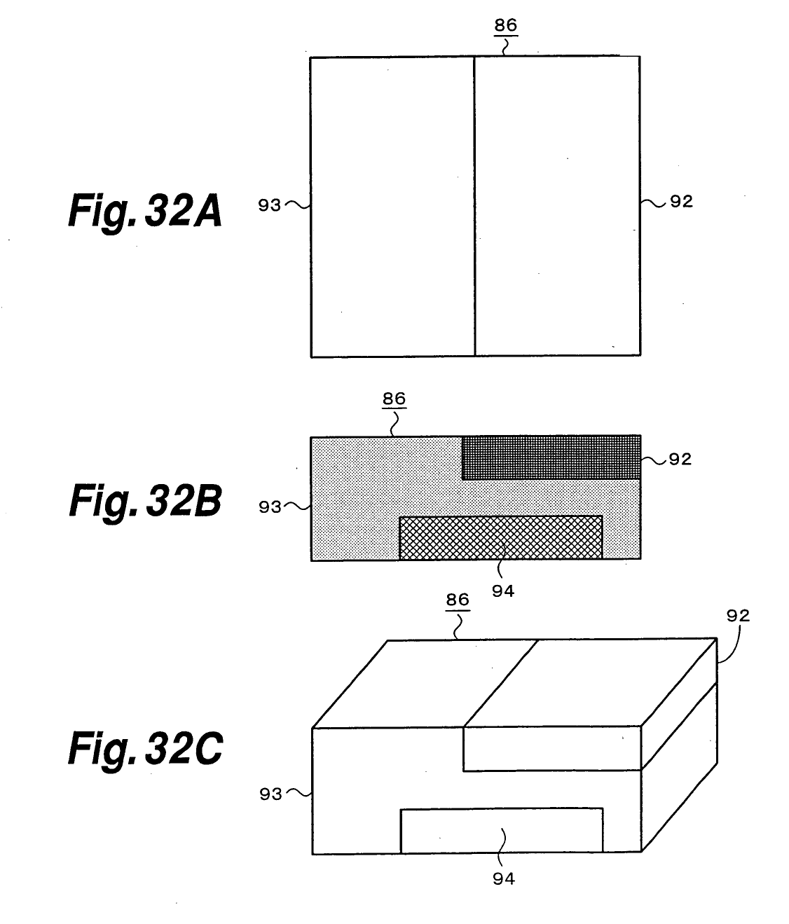

FIGS. 32A to 32C are a plan view, across sectional view, and a perspective view of a composite board 86 obtained by adding a non-metal plate 94 into the space in a right lower portion of the composite board 85 having the shape shown in FIG. 31B, respectively. Even if large pressure is applied upon electric resistance welding, since a metal plate 93 of a low resistance is supported by the non-metal plate 94, the metal plate 93 of a low resistance is not deformed.

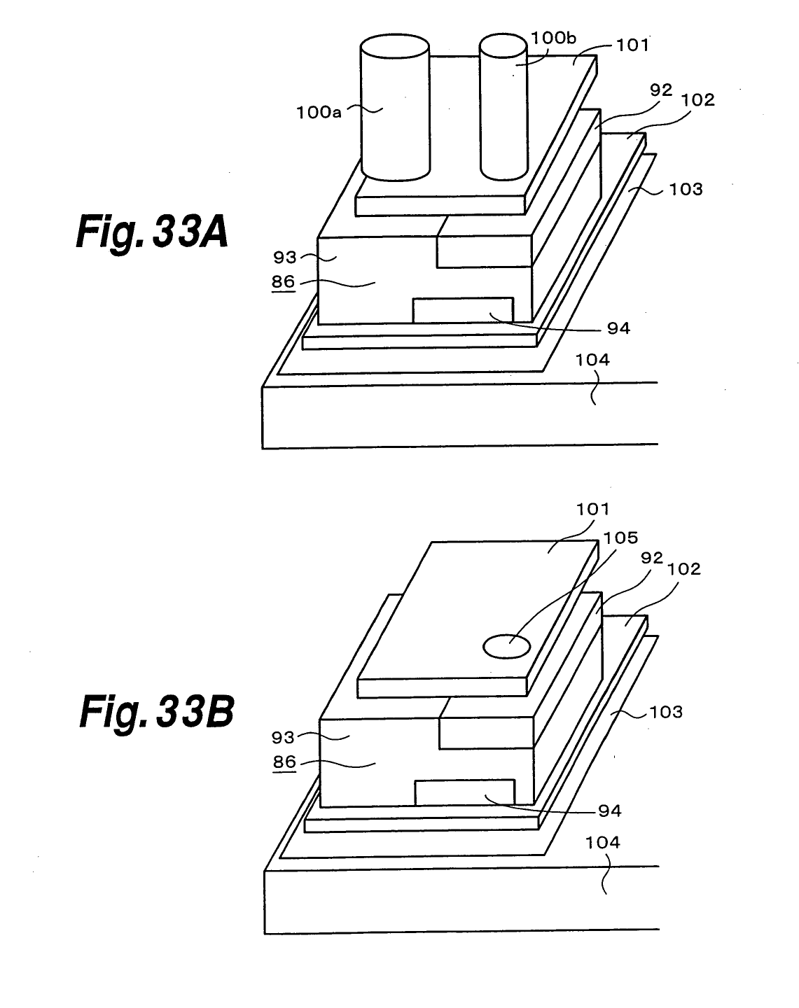

FIGS. 33A and 33B are perspective views when electric resistance welding is performed by using the composite board 86 shown in FIG. 32C. The composite board 86 is formed by bonding the weldable metal plate 92 having excellent electric resistance weldability, a metal plate 93 of a low resistance, and the non-metal plate 94, A metal plate 101 is arranged on the composite board 86. A plus resistance welding rod 100a and a minus resistance welding rod 100b are arranged on the metal plate 101. A diameter of the plus resistance welding rod 100a is larger than that of the minus resistance welding rod 100b. For example, the diameter of the plus resistance welding rod 100a is equal to 3 mm and the diameter of the minus resistance welding rod 100b is equal to 1.5 mm. The plus resistance welding rod 100a and the minus resistance welding rod 100b are pressed downward. With this construction, when electric resistance welding is performed and a large current is supplied to the plus resistance welding rod 100a and the minus resistance welding rod 100b, the weldable metal plates 92 and 101 are bonded under the minus resistance welding rod 100b. The composite board 86 and the metal plate 101 are not bonded under the plus resistance welding rod 100a for the following two reasons.

(1) The metal plate 93 of the low resistance as a metal which is not easily resistance welded is arranged under the plus resistance welding rod 100a.

(2) Since the diameter of the resistance welding rod 100a is large, the current flows in the joint portion of a wide range of the upper portion of the composite board 86 and the metal plate 101.

Upon electric resistance welding, the large current flows in the resistance welding portion under the minus resistance welding rod 100b and the resistance welding portion is heated to high temperature that is equal to or higher than melting points of the composite board 86 and the metal plate 101. At this time, since the non-metal plate 94 of the low heat conductivity is arranged between the resistance welding portion and solder 102, heat conductivity between the resistance welding portion and the solder 102 is extremely low, so that high temperature in the resistance welding portion does not reach the solder 102 in the lower portion. Therefore, such an inconvenience that upon electric resistance welding, the solder 102 is fused or evaporated and vaporized and bonding strength of the metal plate 93 of the low resistance and a circuit board 104 decreases does not occur. Such an inconvenience that the solder 102 is fused and scatters to the periphery, solder balls are deposited to electronic parts of the circuit board, and a short-circuit is caused does not occur, either.

In the composite board 86 having such a shape, even when pressure which is applied upon electric resistance welding is large, since the pressure is supported by the non-metal plate 94, there is not a possibility that the center portion of the metal plate 93 of the low resistance is crushed and deformed. Therefore, if the metal plate 93 of the low resistance to which the invention is applied is used, the solder 102 under the metal plate 93 of the low resistance is not fused and a predetermined welding current can be allowed to flow.

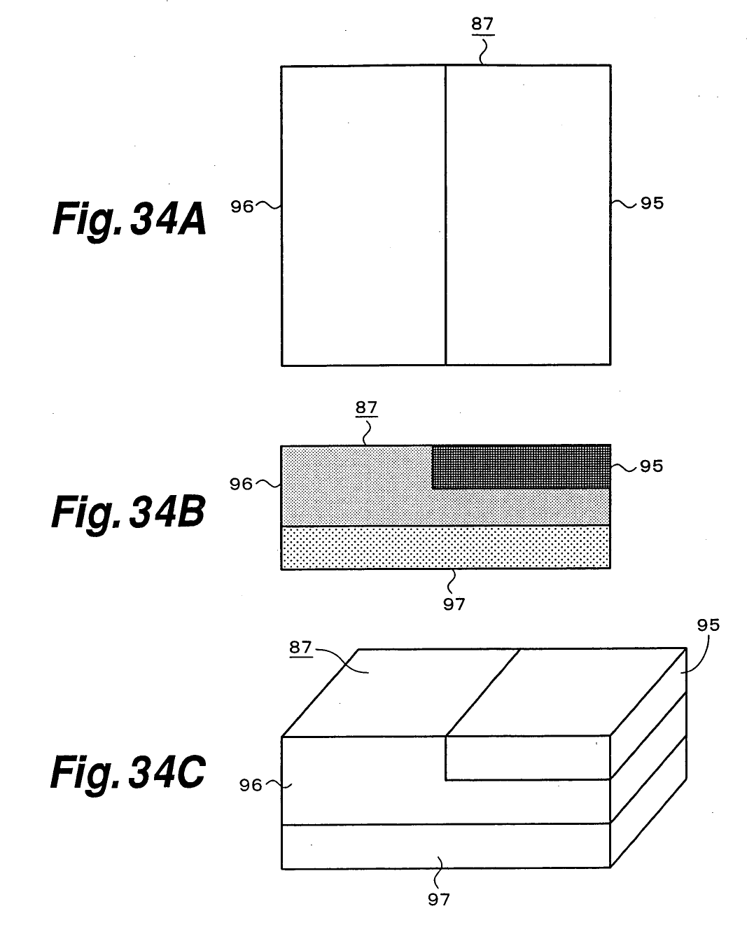

FIGS. 34A to 34C are a plan view, a cross sectional view, and a perspective view showing a composite board 87 obtained by bonding a weldable metal plate 95 having excellent electric resistance weldability, a metal plate 96 of a low resistance, and a metal plate 97 of low heat conductivity, respectively. A concave portion is formed in a right upper portion of the metal plate 96 of the low resistance and the weldable metal plate 95 is bonded there. Since the metal plate 97 of the low heat conductivity exists under the metal plate 96, when they are electric resistance welded, high temperature of a welding portion is insulated to a certain extent by the metal plate of the low heat conductivity. Therefore, high temperature of an upper central portion does not easily reach a lower portion and the solder existing under the upper central portion is not fused.

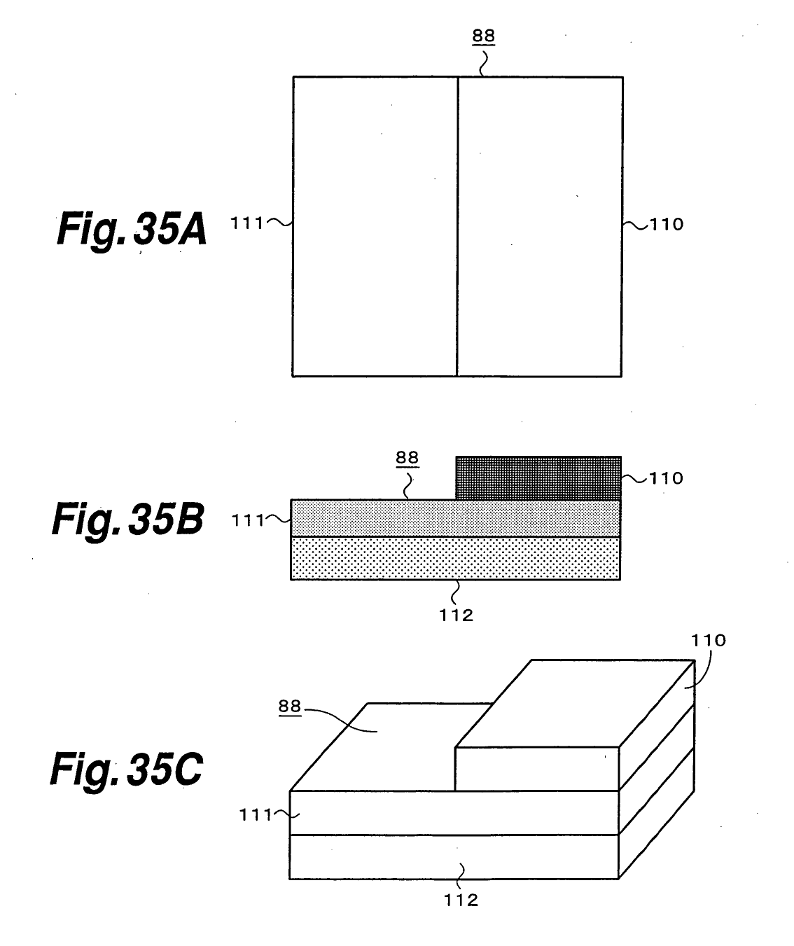

FIGS. 35A to 35C are a plan view, across sectional view, and a perspective view of a composite board 88 obtained by bonding a weldable metal plate 110 having excellent electric resistance weldability, a metal plate 111 of a low resistance, and a metal plate 112 of low heat conductivity, respectively. The weldable metal plate 110 has about a half size of that of the metal plate 111 of the low resistance and is bonded to the right upper surface of the metal plate 111 of the low resistance. Another metal plate is electric resistance welded to the weldable metal plate 110. When another metal plate to be welded is thin, the composite board 88 enables it to be effectively electric resistance welded.

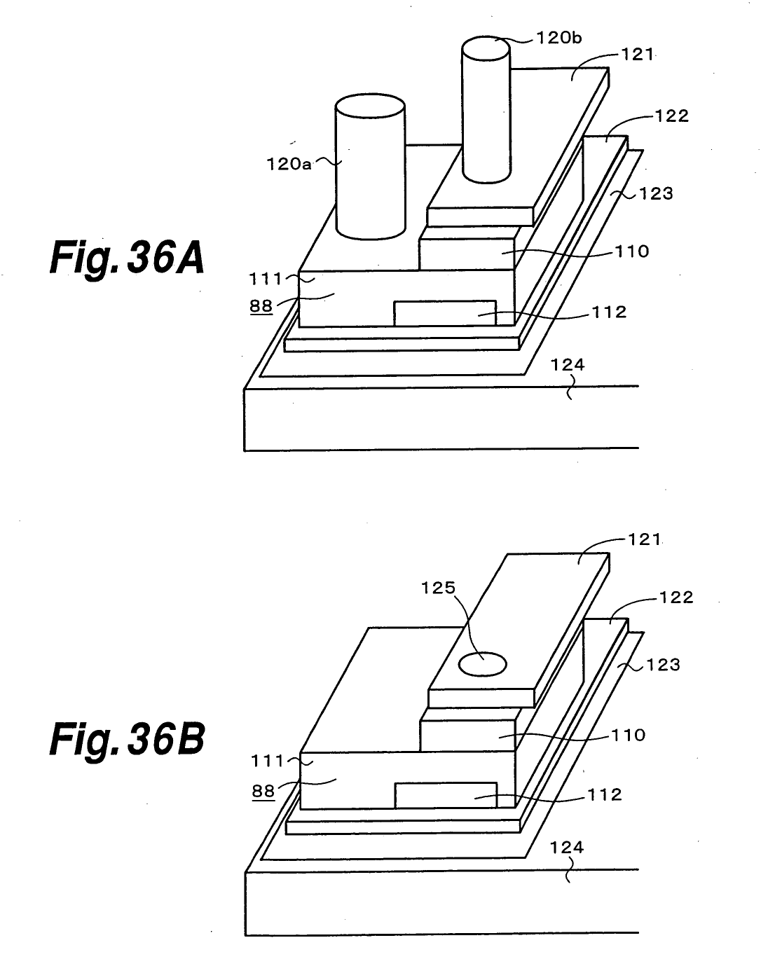

FIGS. 36A and 36B are perspective views when the composite board 88 is electric resistance welded to a metal plate 121. The metal plate 121 is arranged on the weldable metal plate 110 on a right upper portion of the composite board 88. A minus resistance welding rod 120b is arranged on the metal plate 121. A plus resistance welding rod 120a is arranged on the metal plate 111 of the low resistance. A diameter of the plus resistance welding rod 120a is larger than that of the minus resistance welding rod 120b. For example, the diameter of the plus resistance welding rod 120a is equal to 3 mm and the diameter of the minus resistance welding rod 120b is equal to 1.5 mm. The plus resistance welding rod 120a and the minus resistance welding rod 120b are pressed downward. In this construction, when electric resistance welding is performed and a large current is supplied to the plus resistance welding rod 120a and the minus resistance welding rod 120b, the weldable metal plate 110 and the metal plate 121 are bonded under the minus resistance welding rod 120b.

The metal plate 111 of the low resistance and the metal plate 121 are not bonded under the plus resistance welding rod 120a because and the metal plate 121 does not exist. Upon electric resistance welding, a large current flows in a resistance welding portion under the minus resistance welding rod 120b and the resistance welding portion is heated to high temperature that is equal to or higher than melting points of the weldable metal plate 110 and the metal plate 121. At this time, since the metal plate 112 of the low heat conductivity is arranged between the resistance welding portion and solder 122, heat conductivity between the resistance welding portion and solder 122 is extremely low and high temperature in the resistance welding portion does not reach the solder 122 in the lower portion.

A temperature of a portion under the plus resistance welding rod 120a does not become locally high for the following reasons.

(1) Since a resistance value of the metal plate 111 of the low resistance itself is low, an amount of heat generation by the welding current is small.

(2) Since the welding current flows in a wide range in the metal plate 111 of the low resistance, heat is generated in a wide range.

Therefore, there is not a possibility of such an inconvenience that upon electric resistance welding, the solder 122 is fused or evaporated and vaporized, so that bonding strength of the composite board 88 and a circuit board 124 decreases. There is not such an inconvenience either that the solder 122 is fused and dispersed to the periphery, solder balls are formed and deposited to electronic parts of the circuit board, and a short-circuit occurs. In the shape of the composite board 88, even when pressure which is applied upon electric resistance welding is large, since the pressure is supported by the metal plate 112, such an inconvenience that the center portion of the composite board 88 is crushed and deformed is avoided.

The invention is not limited to a plurality of embodiments of the invention mentioned above but many modifications and variations are possible within the spirit and scope of the appended claims of the invention. For example, the number, materials, shapes, and positions of the plates constructing the composite board can be freely modified in accordance with situations such as welding environment, facilities, and the like.

As described above, according to the invention, upon welding, the high temperature in the upper layer of the composite board does not easily reach the lower layer, the temperature of the solder which is in contact with the lower layer does not easily become high, and it is possible to prevent the solder from being fused. Therefore, the fused solder is not scattered to the periphery, the solder balls which become a cause of the short-circuit is not formed, and quality of the electric resistance welding can be improved. A decrease in mounting strength due to the soldering does not occur and the circuit board which is mechanically stable can be formed.

1. (canceled)

2. A structure of a terminal member comprising:
an electrode land formed on a circuit board having an electric wiring; and
a composite board fixed to said electrode land by solder,
wherein at least a part of said composite board has a triple-layer structure and a low heat conductivity plate whose heat conductivity is lower than that of an upper layer or a lower layer is located in an intermediate layer, and
a high heat conductivity plate whose heat conductivity is higher than that of the upper layer is located in the lower layer.

3. A structure of a terminal member comprising:
an electrode land formed on a circuit board having an electric wiring; and
a composite board fixed to said electrode land by solder,
wherein at least a part of said composite board has a triple-layer structure and a low heat conductivity plate whose heat conductivity is lower than that of an upper layer or a lower layer is located in an intermediate layer, and
a high heat conductivity plate whose heat conductivity is higher than that of the lower layer is located in the upper layer.

4. A structure of a terminal member comprising:
an electrode land formed on a circuit board having an electric wiring; and
a composite board fixed to said electrode land by solder,
wherein at least a part of said composite board has a double-layer structure and in one layer, a low heat conductivity plate whose heat conductivity is lower than that of the other layer is located.

5. A structure of a terminal member comprising:
an electrode land formed on a circuit board having an electric wiring; and
a composite board fixed to said electrode land by solder,
wherein at least a part of said composite board has a triple-layer structure and a low heat conductivity plate whose heat conductivity is lower than that of a lower layer is located in an upper layer, and
a metal plate of a low resistance is located in an intermediate layer.

6. A structure of a terminal member comprising:
an electrode land formed on a circuit board having an electric wiring; and
a composite board fixed to said electrode land by solder,
wherein at least a part of said composite board has a triple-layer structure and a low heat conductivity plate whose heat conductivity is lower than that of an upper layer is located in a lower layer, and
a metal plate of a low resistance is located in an intermediate layer.

7. A structure according to any one of claims 1 to 6, wherein said low heat conductivity plate is made of one of an epoxy resin containing glass fiber, a borated binder containing glass fiber, Teflon, plastics, a glass fiber cloth, asbestos, paper, carbon, ceramics, lead, lead alloy, iron, iron alloy, titanium, titanium alloy, tin, tin alloy, and nickel alloy.

8. A structure according to any one of claims 1 to 6, wherein a shape of said composite board is a concave shape.

9. A structure according to claim 8, wherein a plurality of projecting portions are arranged on the inner surface of said concave-shaped composite board so as to face each other.

10. A structure according to any one of claims 1 to 6, wherein a plurality of convex portions are formed in an upper portion of a metal plate which is laminated in an upper layer.

11. A structure according to any one of claims 1 to 6, wherein a whole or a part of said composite board is plated with a metal having anticorrosion performance.

12. A structure according to any one of claims 1 to 6, wherein
one of metal plates of the upper layer and the lower layer constructing said composite board contains at least one or more kinds of nickel, nickel alloy, iron, iron alloy, stainless steel, zinc, and zinc alloy, and
said metal plate of the low resistance contains at least one or more kinds of copper, copper alloy, silver, silver alloy, gold, gold alloy, platinum, platinum alloy, aluminum, aluminum alloy, tungsten, tungsten alloy, beryllium, beryllium alloy, rhodium, and rhodium alloy.

13. A structure according to any one of claims 1 to 6, wherein a plurality of plates forming said composite board are diffusion bonded by a method of heating and pressing them in the vertical direction.

14. A structure according to any one of claims 1 to 6, wherein a plurality of plates forming said composite board are diffusion bonded by a method of pressing them in the vertical direction while applying an ultrasonic vibration.

15. A structure according to any one of claims 1 to 6, wherein plates forming said composite board are heated, fused, and bonded by electric resistance welding such as spot welding or seam welding.

16. A structure according to any one of claims 1 to 6, wherein plates forming said composite board are bonded by a method whereby joint surfaces are coated with a conductive adhesive agent and said plates are pressed while heating or without heating.

17. A structure according to any one of claims 1 to 6, wherein plates forming said composite board are bonded by a method whereby a laser beam is irradiated to a part of a metal plate made of a single material, a rectangular space which penetrates said metal plate is formed, heated liquid plastics or plastics containing glass fiber are inserted into said space, the liquid plastics or the plastics containing the glass fiber are cooled and solidified.

18. A structure according to any one of claims 1 to 6, wherein a surface of a part of a metal plate made of a single material is etched by a chemical etching treatment, an etching concave portion is formed, a heat insulating plate made of plastics or the like is arranged in said concave portion, a metal plate is adhered onto an upper portion of said heat insulating plate, and the two metal plates are bonded, so that the composite board of a triple structure is formed.

19. A structure according to any one of claims 8 to 10, wherein two or more convex shapes or one or more concave shape of the surface of said composite board are bonded by a chemical etching treatment.
